(19) United States
(12) Patent Application Publication
(10) Pub. No.: US 2023/0397434 A1
(43) Pub. Date: Dec. 7, 2023

(54) MEMORY DEVICE ASSEMBLY WITH REDISTRIBUTION LAYER BETWEEN TRANSISTORS AND CAPACITORS

(71) Applicant: Micron Technology, Inc., Boise, ID (US)

(72) Inventors: Marcello MARIANI, Milano (IT); Giorgio SERVALLI, Fara Gera d'Adda (IT)

(21) Appl. No.: 17/812,233

(22) Filed: Jul. 13, 2022

Related U.S. Application Data
(60) Provisional application No. 63/365,637, filed on Jun. 1, 2022.

(51) Int. Cl. H01L 27/11507

(52) U.S. Cl. CPC H01L 27/11507

(57) ABSTRACT

A memory device includes an array of memory cells. A memory cell includes a transistor with a pillar that includes an upper source/drain, a lower source/drain, and a channel between the upper source/drain and the lower source/drain. The transistor includes a gate that is part of a gate line and that is proximate to the channel. The memory cell includes a capacitor having a bottom electrode, an insulator, and a top electrode. The memory cell includes a conductive contact region that couples the transistor and the capacitor and that includes the upper source/drain, a first conductive region having a right surface that abuts the upper source/drain and having a left surface that contacts a first insulator line, and a second conductive region having a left surface that abuts the upper source/drain and having a right surface that contacts a second insulator line that is parallel to the first insulator line.

### CROSS-REFERENCE TO RELATED APPLICATION

This patent application claims priority to U.S. Provisional Patent Application No. 63/365,637, filed on Jun. 1, 2022, and entitled “MEMORY DEVICE ASSEMBLY WITH REDISTRIBUTION LAYER BETWEEN TRANSISTORS AND CAPACITORS.” The disclosure of the prior application is considered part of and is incorporated by reference into this patent application.

### TECHNICAL FIELD

The present disclosure generally relates to semiconductor devices and methods of forming semiconductor devices. For example, the present disclosure relates to a memory device assembly with a redistribution layer between transistors and capacitors.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell.

FIG. 2 is a diagram illustrating a top view of an example array of transistors.

FIG. 3 is a diagram illustrating a top view of an example array of capacitors on top of the array of transistors shown in FIG. 2.

FIGS. 4A-4B are diagrammatic views of an example structure described herein. FIG. 4A is a top view, and FIG. 4B is a side cross-sectional view along the line 4B-4B of FIG. 4A.

FIG. 5 is a diagrammatic view of an example structure that includes capacitors in contact with a conductive contact region of the structure of FIG. 4.

FIG. 6 is a flowchart of an example method of forming an integrated assembly or memory device having a redistribution layer between transistors and capacitors.

FIGS. 7A and 7B are diagrammatic views showing formation of the structure of FIGS. 4A-4B at an example process stage of an example process of forming the structure. FIG. 7A is a top view, and FIG. 7B is a cross-sectional view along the line 7B-7B of FIG. 7A.

FIGS. 8A and 8B are diagrammatic views showing formation of the structure of FIGS. 4A-4B at an example process stage that is after the example process stage of FIGS. 7A and 7B. FIG. 8A is a top view, and FIG. 8B is a cross-sectional view along the line 8B-8B of FIG. 8A.

FIGS. 9A and 9B are diagrammatic views showing formation of the structure of FIGS. 4A-4B at an example process stage that is after the example process stage of FIGS. 8A and 8B. FIG. 9A is a top view, and FIG. 9B is a cross-sectional view along the line 9B-9B of FIG. 9A.

FIGS. 10A and 10B are diagrammatic views showing formation of the structure of FIGS. 4A-4B at an example process stage that is after the example process stage of FIGS. 9A and 9B. FIG. 10A is a top view, and FIG. 10B is a cross-sectional view along the line 10B-10B of FIG. 10A.

FIGS. 11A and 11B are diagrammatic views showing formation of the structure of FIGS. 4A-4B at an example process stage that is after the example process stage of FIGS. 10A and 10B. FIG. 11A is a top view, and FIG. 11B is a cross-sectional view along the line 11B-11B of FIG. 11A.

FIGS. 12A and 12B are diagrammatic views showing formation of the structure of FIGS. 4A-4B at an example process stage that is after the example process stage of FIGS. 11A and 11B. FIG. 12A is a top view, and FIG. 12B is a cross-sectional view along the line 12B-12B of FIG. 12A.

FIGS. 13A and 13B are diagrammatic views showing formation of the structure of FIGS. 4A-4B at an example process stage that is after the example process stage of FIGS. 12A and 12B. FIG. 13A is a top view, and FIG. 13B is a cross-sectional view along the line 13B-13B of FIG. 13A.

FIGS. 14A and 14B are diagrammatic views showing formation of the structure of FIGS. 4A-4B at an example process stage that is after the example process stage of FIGS. 13A and 13B. FIG. 14A is a top view, and FIG. 14B is a cross-sectional view along the line 14B-14B of FIG. 14A.

FIGS. 15A and 15B are diagrammatic views showing formation of the structure of FIGS. 4A-4B at an example process stage that is after the example process stage of FIGS. 14A and 14B. FIG. 15A is a top view, and FIG. 15B is a cross-sectional view along the line 15B-15B of FIG. 15A.

FIG. 16 is a diagrammatic view of an example memory device.

### DETAILED DESCRIPTION

Some memory cell arrays may be fabricated with transistors that are arranged in a rectangular pattern. A transistor portion of a memory cell may include a transistor pillar (e.g., that includes a source, a drain, and a channel between the source and the drain), one or more gates of the transistor, insulative material used to separate the transistor pillar from the one or more gates, and insulative material used to separate the memory cell from adjacent memory cells. In the rectangular pattern, the transistor portion of each memory cell may be rectangular (e.g., when viewed from above), where a distance between adjacent pillars is greater in one direction (e.g., along a digit line) as compared to another direction (e.g., along an access line). This arrangement has certain advantages, such as the ability to include multiple gates per transistor pillar to improve current flow, the ability to tightly pack a large number of transistor on a die (e.g., as compared to a square pattern), or the like.

In some cases, a capacitor portion of a memory cell may be fabricated to have a cylindrical shape, such as with a bottom electrode cylinder that is encircled by an insulator, which is encircled by a top electrode. This shape may have certain advantages, such as good electrical properties, the ability to tightly pack a large number of capacitors on a die (e.g., as compared to other shapes), or the like.

However, when an array of cylindrical capacitors is to be fabricated on top of an array of transistors arranged in a rectangular pattern, the bottom electrodes of the capacitors may not be directly on top of the transistor pillar. This may lead to poor electrical properties or the inability of the capacitor to store charge. Some implementations described herein enable good electrical coupling between transistors and capacitors via a redistribution layer.

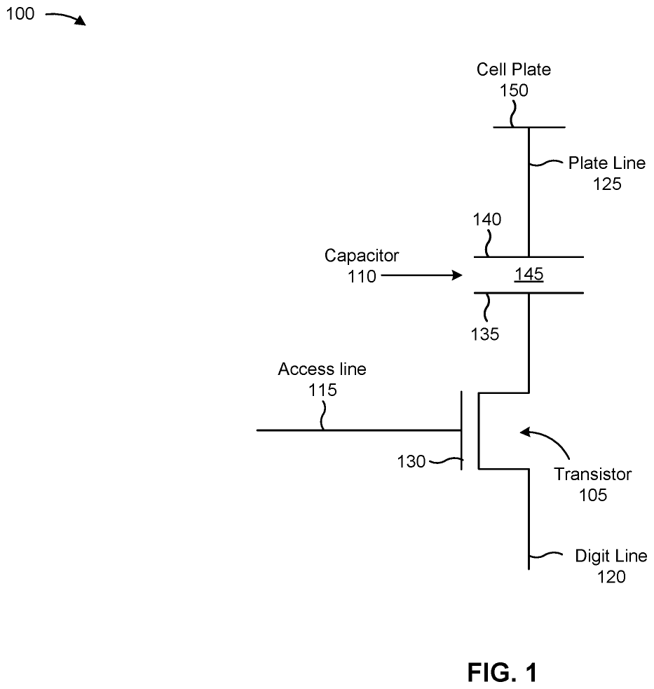

FIG. 1 is a circuit diagram of an example memory cell 100. In some implementations, the memory cell 100 is a ferroelectric memory cell. Alternatively, the memory cell 100 may be a linear dielectric memory cell or a paraelectric memory cell. As shown in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a digit line 120 (sometimes called a “bit line”), and a plate line 125.

The transistor 105 (sometimes called an access transistor) may include a gate 130. The capacitor 110 includes a bottom electrode 135 and a top electrode 140 separated by an insulator 145. In some implementations, the capacitor is a ferroelectric capacitor, and the insulator 145 is a ferroelectric insulator that comprises, consists of, or consists essentially of ferroelectric material. Alternatively, the capacitor may be a linear dielectric capacitor, and the insulator 145 may be a linear dielectric insulator that comprises, consists of, or consists essentially of linear dielectric material. Alternatively, the capacitor may be a paraelectric capacitor, and the insulator 145 may be a paraelectric insulator that comprises, consists of, or consists essentially of paraelectric material. When the access line 115 is activated (e.g., when a voltage is applied to the access line 115), the gate 130 coupled to the access line 115 may be activated. When the gate 130 is activated, the transistor 105 couples the digit line 120 to the bottom electrode 135 of the capacitor 110. A state of the memory cell 100 may then be written or read via the digit line 120.

The top electrode 140 of the capacitor 110 may be coupled to the plate line 125 and a cell plate 150. To write to (or program) the memory cell 100, the access line 115 may be activated, and a voltage may be applied across the capacitor 110 by controlling the voltage of the top electrode 140 (via the plate line 125 and/or the cell plate 150) and/or the bottom electrode 135 (via the digit line 120).

For a ferroelectric capacitor, the applied voltage creates an electric field, and the atoms in the ferroelectric material of the insulator 145 respond to the electric field to become arranged in a particular state (e.g., a particular orientation or polarization), which is representative of a data state (e.g., a logic “0” state or a logic “1” state). In some implementations, data may be stored using the capacitor 110 by controlling a voltage difference and/or a polarity difference of the capacitor 110 (e.g., of the insulator 145 between the bottom electrode 135 and the top electrode 140). For example, a voltage of the cell plate 150 and the digit line 120 may be controlled. In some implementations, a negative polarity of the insulator 145 as compared to the cell plate 150 results in a logic “0” state being stored in the capacitor 110, and a positive polarity of the insulator 145 as compared to the cell plate 150 results in a logic “1” state being stored in the capacitor 110. For a linear dielectric capacitor or a paraelectric capacitor, the cell plate 150 may grounded, and the capacitor 110 may be charged by applying a voltage to the bottom electrode 135 via the digit line 120.

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The magnitude of the change in stored charge may depend on the stored state of capacitor 110 (e.g., whether the stored state is a logic “1” state or a logic “0” state). This may or may not induce a threshold change in the voltage of the digit line 120 based on the charge stored on the capacitor 110. The change in voltage or lack of change in voltage of the digit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

As indicated above, FIG. 1 is provided as an example. Other examples may differ from what is described with respect to FIG. 1.

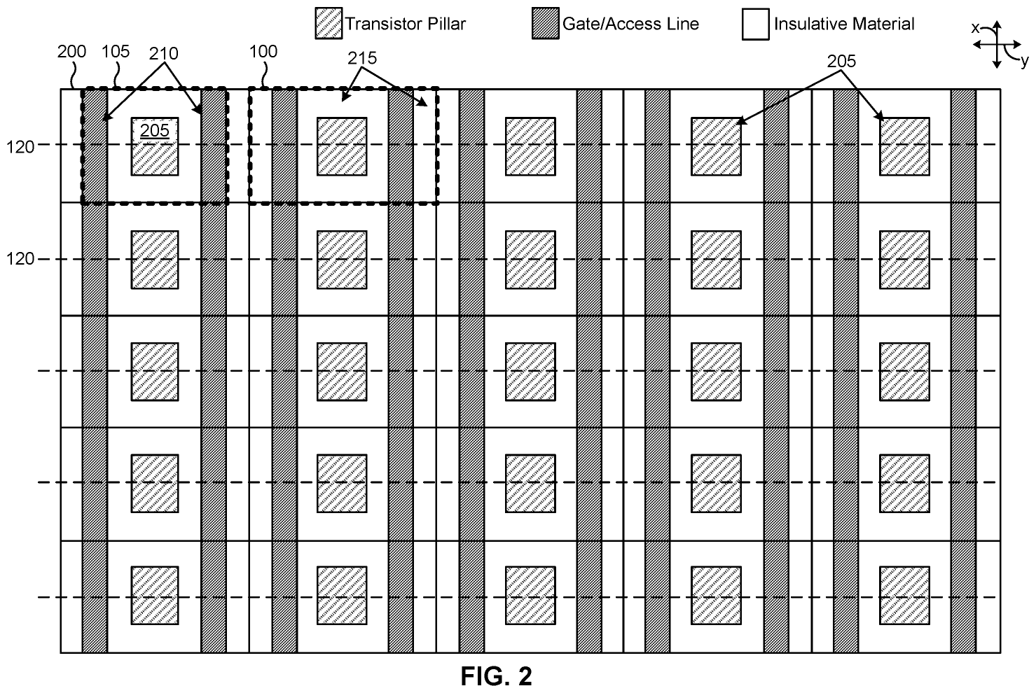

FIG. 2 is a diagram illustrating a top view of an example array 200 of transistors 105. As shown, a transistor 105 may include a transistor pillar 205 (e.g., with a source, a drain, and a channel connecting the source and the drain) and one or more gates 210 (e.g., that together form a gate 130). In FIG. 2, a transistor 105 is shown as including two gates, which may be electrically coupled (e.g., at an edge of the array) to form an access line 115 used to access that transistor 105 (e.g., along with a digit line 120). The transistor 105 may form part of a memory cell 100 (e.g., along with a capacitor 110, not shown in FIG. 2).

As further shown in FIG. 2, a transistor portion of a memory cell 100 may include the transistor pillar 205, one or more gates 210 of the transistor, and insulative material 215, which may separate the transistor pillar 205 from the one or more gates 210 and/or may separate the memory cell 100 from adjacent memory cells (e.g., may separate gates 210 of adjacent memory cells and/or may separate transistor pillars 205 of adjacent memory cells). As shown, the transistor portion of the memory cell 100 is rectangular, where a length of the memory cell 100 is greater in the illustrated y-direction (e.g., in a digit line direction) as compared to a length of the memory cell 100 in the illustrated x-direction (e.g., in an access line direction or a gate line direction). In other words, a distance between adjacent transistor pillars 205 is larger along the digit line and is smaller along the access line.

As an example, the transistor portion of the memory cell 100 may have a length of 40 nanometers in the illustrated x-direction and 24 nanometers in the illustrated y-direction. For example, a transistor pillar 205 may be 12 nanometers wide in the y-direction, and adjacent transistor pillars 205 may be spaced apart by 12 nanometers in the y-direction, thus resulting in a pitch of 24 nanometers in the y-direction. Additionally, or alternatively, a transistor pillar 205 may be 10 nanometers wide in the x-direction, each gate 210 may have a width of 5 nanometers in the x-direction, a transistor pillar 205 may be separated from each gate by 5 nanometers in the x-direction (e.g., 5 nanometers on the left of the transistor pillar 205 that separates the transistor pillar 205 from a first gate 210, and 5 nanometers on the right of the transistor pillar 205 that separates the transistor pillar 205 from a second gate 210), and adjacent gates 210 that control access to different transistor pillars 205 may be separated by 10 nanometers in the x-direction, thus resulting in a pitch of 40 nanometers in the y-direction. All of these example dimensions are approximate values within reasonable tolerances of manufacturing and measurement. This 40 nanometer by 24 nanometer pitch (as an example) results in transistors that are arranged in a rectangular pattern, as shown.

As indicated above, FIG. 2 is provided as an example. Other examples may differ from what is described with respect to FIG. 2.

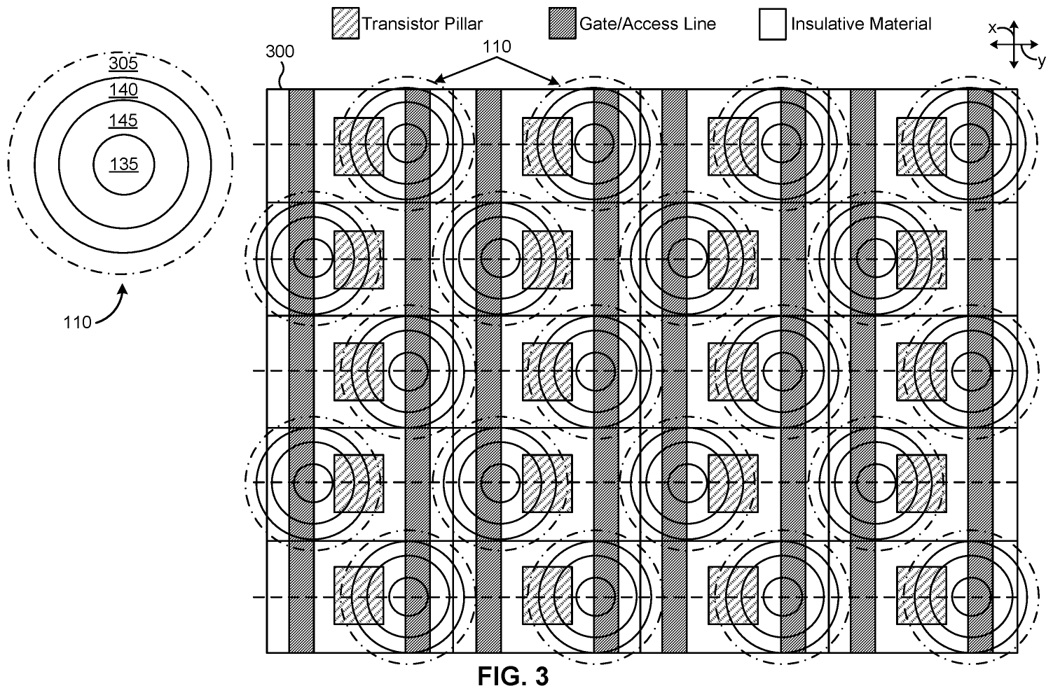

FIG. 3 is a diagram illustrating a top view of an example array 300 of capacitors 110 on top of the array 200 of transistors 105 shown in FIG. 2. As shown in FIG. 3, a capacitor 110 may include a bottom electrode 135 (e.g., that is cylindrical in shape), an insulator 145 around the vertical surface of the bottom electrode 135, and a top electrode 140 around a vertical surface of the insulator 145. As further shown in FIG. 3, each capacitor 110 may be associated with a tolerance region 305 to prevent capacitors 110 of different memory cells 100 from coming in contact with one another and/or impacting one another.

In some implementations, components of the capacitor 110 are equal to or greater than a certain size to achieve good electrical properties and/or a sufficient level of performance and/or reliability for use in a memory device. For example, the capacitor 110 may have a diameter of approximately 30 nanometers, including the tolerance region 305. For example, a diameter of the bottom electrode 135 may be approximately 8.6 nanometers, the illustrated annulus of the insulator 145 may be approximately 5.1 nanometers wide, the illustrated annulus of the top electrode 140 may be approximately 3 nanometers wide, and the illustrated annulus of the tolerance region 305 may be approximately 2.6 nanometers wide.

When cylindrical capacitors 110 (sometimes called stud capacitors) having a particular size are formed on top of the array 200 of transistors 105 arranged in a rectangular pattern, a bottom electrode 135 of a capacitor 110 may not contact the transistor pillar 205, thus rendering the resulting structure incapable of storing data (e.g., because the bottom electrode 135 of the capacitor 110 cannot be accessed via the transistor pillar 205). Alternatively, the bottom electrode 135 may not sufficiently contact the transistor pillar 205, which may lead to unreliable or poor performance of a resulting memory device. Some implementations described herein enable transistors 105 (e.g., transistor pillars 205) and capacitors 110 (e.g., bottom electrodes 135) arranged in such a manner to have improved electrical coupling via a redistribution layer.

As indicated above, FIG. 3 is provided as an example. Other examples may differ from what is described with respect to FIG. 3.

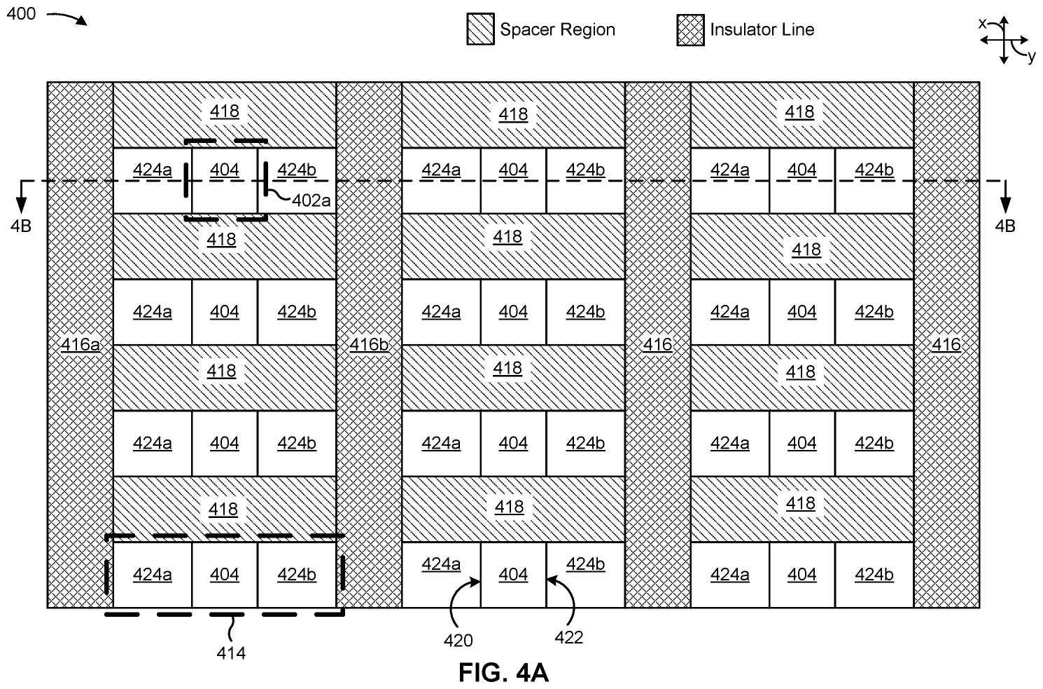

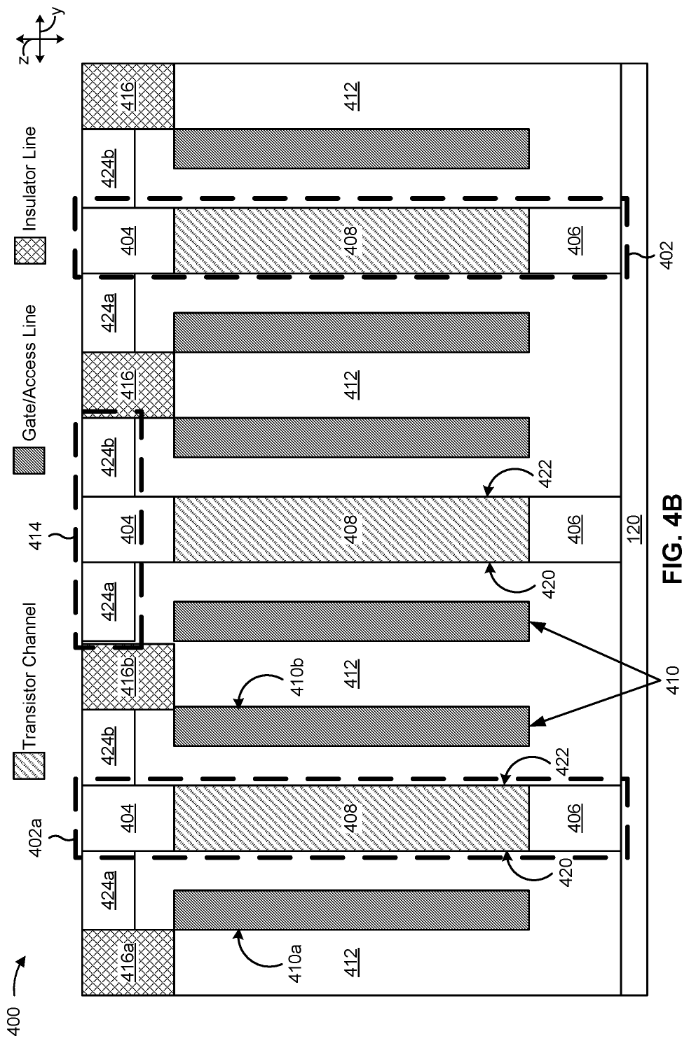

FIGS. 4A-4B are diagrammatic views of an example structure 400. The structure 400 may be part of an integrated assembly, such as a memory array, a portion of a memory array, or a memory device that includes the memory array and one or more other components (e.g., sense amplifiers, a row decoder, a column decoder, a row address buffer, a column address buffer, one or more data buffers, one or more clocks, one or more counters, and/or a memory controller).

As shown in FIGS. 4A-4B, the structure 400 includes multiple pillars 402, which may correspond to the transistor pillars 205 described elsewhere herein. A pillar 402 may include an upper source/drain 404, a lower source/drain 406, and a channel 408 between the upper source/drain 404 and the lower source/drain 406. The structure 400 may also include multiple gate lines 410, insulative material 412, multiple conductive contact regions 414, multiple insulator lines 416, multiple spacer regions 418, and multiple digit lines 120. The structure 400 may include other parts not shown in FIGS. 4A-4B, such as one or more parts described above in connection with FIGS. 1-3.

As shown, the upper source/drain 404 is at or on the top of the pillar 402, and the lower source/drain 406 is at or on the bottom of the pillar 402. The channel 408 (sometimes called a junction) is beneath and/or abutting the upper source/drain 404 and is above and/or abutting the lower source/drain 406. The pillar 402 has a left-facing vertical surface 420 facing a first direction along a first axis (e.g., the illustrated y-axis), and a right-facing vertical surface 422 facing a second direction that is opposite the first direction along the first axis (e.g., the illustrated y-axis). The pillar 402 extends vertically along a second axis (e.g., the illustrated z-axis of FIG. 4B) that is perpendicular to the first axis. In some implementations, the pillar 402 is a rectangular prism (with six surfaces) or approximately a rectangular prism. Additionally, or alternatively, the upper source/drain 404, the lower source/drain 406, and/or the channel 408 may be a rectangular prism (or approximately a rectangular prism).

A pillar 402 may be a semiconductor and may comprise, consist of, or consist essentially of semiconductor material. The semiconductor material may comprise, consist of, or consist essentially of one or more of silicon, germanium, gallium arsenide, or any other chemical element or chemical compound capable of acting as a semiconductor. In some implementations, the semiconductor material may comprise, consist of, or consist essentially of doped silicon. The silicon may be, for example, monocrystalline silicon, polycrystalline silicon, or amorphous silicon.

The upper source/drain 404 and/or the lower source/drain 406 (referred to collectively as “source/drains”) may be doped semiconductors and may comprise, consist of, or consist essentially of doped semiconductor material, such as n-type doped semiconductor material. The source/drains may be n-type doped by incorporating a chemical element or chemical compound that includes electron donor atoms (e.g., phosphorous and/or arsenic) into the semiconductor material (e.g., silicon). In some implementations, the source/drains may be heavily doped.

In some implementations, one or more of the source/drains may comprise, consist of, or consist essentially of conductive material (e.g., other than the doped semiconductor material). For example, one or more of the source/drains may comprise, consist of, or consist essentially of a metal silicide (e.g., titanium silicide and/or tungsten silicide) and/or other conductive material (e.g., titanium and/or tungsten). In some implementations, the upper source/drain 404 and/or the lower source/drain 406 may cap the pillar 402, such that that the upper source/drain 404 and/or the lower source/drain 406 does not include the semiconductor material of the pillar 402.

The channel 408 may be an intrinsic semiconductor and may comprise, consist of, or consist essentially of intrinsic semiconductor material, such as undoped semiconductor material. Alternatively, the channel 408 may be lightly doped using n-type doping. However, the source/drains may be more heavily doped (e.g., with more electron donor atoms) than the channel 408.

A gate line 410 may extend through the structure 400 in the illustrated x-direction. A portion of the gate line 410 may be proximate to (e.g., physically near) a pillar 402, and that portion may act as a gate for the pillar 402 (e.g., for a channel 408 of the pillar 402). Different portions of the gate line 410 along the illustrated x-axis may be proximate to different pillars 402 and may act as gates for those pillars 402 when the gate line 410 is activated. As shown, a pillar 402 may be proximate to (e.g., physically near) two gate lines 410, shown as a first gate line 410a and a second gate line 410b. For example, a portion of the first gate line 410a may be proximate to the channel 408 on a first side of the pillar 402 (e.g., the left-facing vertical surface 420). The first gate line 410a may be separated from the channel 408 by the insulative material 412 (e.g., a first gate dielectric). Similarly, a portion of the second gate line 410b may be proximate to the channel 408 on a second side of the pillar 402 (e.g., the right-facing vertical surface 422) that is opposite from the first side. The second gate line 410b may be separated from the channel 408 by the insulative material 412 (e.g., a second gate dielectric). The gate lines 410 may be substantially parallel to one another.

The first gate line 410a and the second gate line 410b may be coupled to one another to form a single access line 115 that controls access to the pillar 402. The portions of the first gate line 410a and the second gate line 410b that are proximate to the channel 408 of the pillar 402 may act as the gate 130. For example, the first gate line 410a and the second gate line 410b may control the flow of current through the channel 408. Gate lines 410 associated with different memory cells (e.g., proximate to different pillars 402) may be separated by the insulative material 412.

The gate lines 410 may be electrical conductors and may comprise, consist of, or consist essentially of electrically conductive material. The electrically conductive material may comprise, consist of, or consist essentially of a metal (e.g., titanium, tungsten, cobalt, nickel, platinum, and/or ruthenium), a metal composition (e.g., a metal silicide, a metal nitride, and/or a metal carbide), and/or a conductively-doped semiconductor material (e.g., conductively-doped silicon, conductively-doped germanium, and/or conductively-doped gallium arsenide).

The insulative material 412 (e.g., the gate dielectrics) may be an electrical insulator capable of being polarized by an applied electric field (e.g., via dielectric polarization) and may comprise, consist of, or consist essentially of dielectric material. The dielectric material may comprise, consist of, or consist essentially of one or more of silicon dioxide, silicon nitride, aluminum oxide, or hafnium oxide, among other examples. In some implementations, the insulative material 412 includes a first material that forms the gate dielectrics and a second material that forms one or more regions other than the gate dielectrics. In some implementations, the insulative material is silicon dioxide.

As shown in FIGS. 4A-4B, the conductive contact region 414 may include the upper source/drain 404 (or a portion of the upper source/drain 404) and two conductive regions 424 (sometimes called conductor lines), shown as a first conductive region 424a (sometimes called a first conductor line) and a second conductive region 424b (sometimes called a second conductor line). As shown, the first conductive region 424a extends along the first axis (e.g., the illustrated y-axis) from the upper source/drain 404 to a first insulator line 416a. The first insulator line 416a is on the first side of the pillar 402 (e.g., the illustrated pillar 402a). In other words, the left-facing vertical surface 420 of the pillar 402a faces a portion of the first insulator line 416a that contacts the first conductive region 424a. Thus, the first conductive region 424a has a right surface that abuts the upper source/drain 404 and has a left surface that contacts the first insulator line 416a. The portion of the first insulator line 416a that contacts the first conductive region 424a is proximate to (e.g., physically near) the upper source/drain 404 on the first side of the pillar 402a.

As further shown, the second conductive region 424b extends along the first axis (e.g., the illustrated y-axis) from the upper source/drain 404 to a second insulator line 416b. The second insulator line 416b is on the second side of the pillar 402 (e.g., the illustrated pillar 402a). In other words, the right-facing vertical surface 422 of the pillar 402a faces a portion of the second insulator line 416b that contacts the second conductive region 424b. Thus, the second conductive region 424b has a left surface that abuts the upper source/drain 404 and has a right surface that contacts the second insulator line that 416b. The portion of the second insulator line 416b that contacts the second conductive region 424b is proximate to (e.g., physically near) the upper source/drain 404 on the second side of the pillar 402a.

As shown in FIG. 4A, the top surface of the conductive contact region 414 may be a rectangle, may be approximately a rectangle, or may be substantially rectangular. As shown in FIG. 4B, the conductive contact region 414 may be horizontally centered with respect to the pillar 402. For example, the conductive contact region 414 may be centered over the channel 408 and/or the upper source/drain 404. In other words, the first conductive region 424a and the second conductive region 424b may be approximately the same size. As further shown in FIG. 4B, a top surface of the conductive contact region 414 (e.g., a top surface of the upper source/drain 404, the first conductive region 424a, and/or the second conductive region 424b) may be substantially horizontally aligned with the top surface of the insulator line 416 (e.g., top surfaces of multiple respective insulator lines 416). As further shown, in some implementations, a bottom surface of the first conductive region 424a and a bottom surface of the second conductive region 424b may be substantially horizontally aligned. In some implementations, the bottom surface of the first conductive region 424a and/or the bottom surface of the second conductive region 424b may be vertically higher than the bottom surface of the upper source/drain 404. In some implementations, the first conductive region 424a and the second conductive region 424b are separated from respective gate lines 410 by the insulative material 412.

The conductive region 424 may be an electrical conductor and may comprise, consist of, or consist essentially of conductive material. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped silicon, conductively-doped germanium, and/or conductively-doped gallium arsenide), among other examples. In some implementations, the first conductive region 424a and the second conductive region 424b may be the same material.

An insulator line 416 may extend through the structure 400 along a third axis (e.g., the x-axis illustrated in FIG. 4A) that is perpendicular to a plane formed by the first axis (the y-axis) and the second axis (the z-axis). The insulator lines 416 may be substantially parallel to one another. The gate lines 410 and the insulator lines 416 may extend in the same direction (e.g., along the x-axis). In some implementations, a bottom surface of an insulator line 416 is substantially horizontally aligned with the bottom surface of the upper source/drain 404, a top surface of a gate line 410, and/or a top surface of the channel 408.

The insulator line 416 may be an electrical insulator and may comprise, consist of, or consist essentially of insulative material. The insulative material may comprise, consist of, or consist essentially of silicon dioxide, silicon nitride, aluminum oxide, and/or hafnium oxide, among other examples. In some implementations, the insulator line 416 is silicon nitride. In some implementations, the insulator line 416 may be a different material than the insulative material 412.

A spacer region 418 (sometimes called an insulative spacer region) may occupy an area bounded by consecutive insulator lines 416 (e.g., two insulator lines 416 that are adjacent or consecutive in the y-direction, with no intervening insulator lines 416) and bounded by consecutive conductive contact regions 414 (e.g., two conductive contact regions 414 that are adjacent or consecutive in the x-direction, with no intervening conductive contact regions 414). Thus, consecutive conductive contact regions 414, included in a column of memory cells that extends along a direction parallel to the insulator lines 416, may be separated by respective spacer regions 418 that each abut two insulator lines 416 (e.g., the first insulator line 416a and the second insulator line 416b). In other words, a spacer region 418 may abut two insulator lines 416 (e.g., the first insulator line 416a and the second insulator line 416b) and may separate a conductive contact region 414 from an adjacent conductive contact region 414 associated with (e.g., abutting or including an upper source/drain 404 of) an adjacent pillar 402. The spacer region 418 may be an electrical insulator and may comprise, consist of, or consist essentially of the insulative material 412.

In some implementations, the structure 400 may include multiple capacitors 110 (not shown in FIGS. 4A-4B). A capacitor may be positioned on top of and/or abutting a conductive contact region 414. A conductive contact region 414 electrically couples the capacitor 110 with an upper source/drain 404. Different capacitors 110 of the structure 400 may be electrically insulated from one another. In some implementations, an electrical component other than a capacitor may be used in place of the capacitor 110 (e.g., for use of the structure 400 in a device other than a memory device).

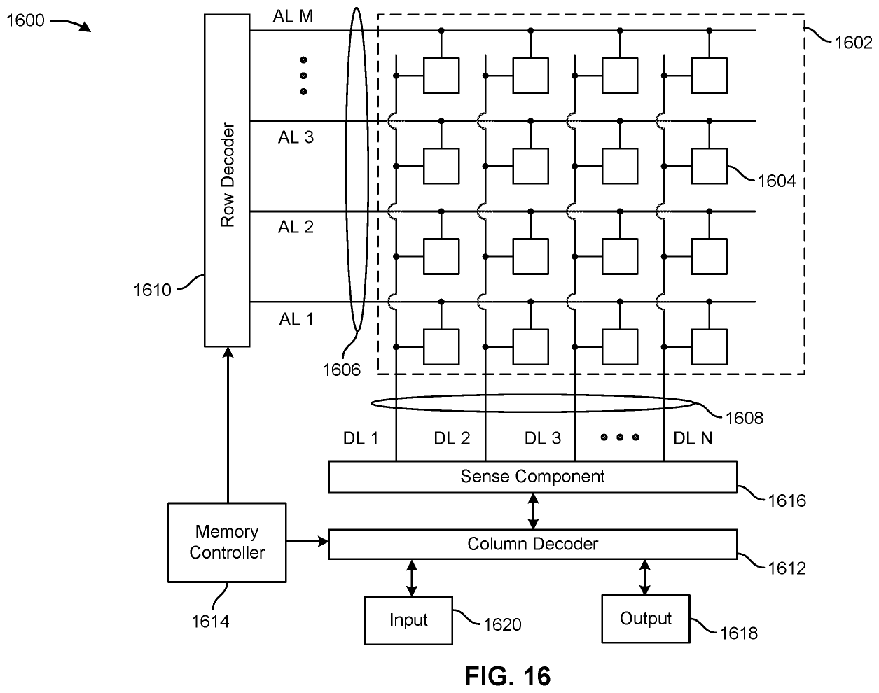

As shown in FIG. 4B, a digit line 120 is beneath a pillar 402 and is electrically coupled with the lower source/drain 406 of the pillar 402. In some implementations, the digit line 120 is beneath and/or abuts the lower source/drain 406 of the pillar 402. The digit line 120 may extend along the first axis (e.g., the y-axis), and may be beneath a set of pillars 402 that is spaced (e.g., substantially evenly) along the first axis. A set of pillars 402 that are in contact with the same digit line may be referred to as a column of pillars (e.g., referring to the row and column terminology described below in connection with FIG. 16). Similarly, a set of pillars 402 that are accessible via the same access line 115 (or pair of gate lines 410) may be referred to as a row of pillars (e.g., referring to the row and column terminology described below in connection with FIG. 16). The digit line 120 may be parallel to the conductive contact region 414 (e.g., the first conductive region 424a and/or the second conductive region 424b).

A digit line 120 may be an electrical conductor and may comprise, consist of, or consist essentially of electrically conductive material. The electrically conductive material may comprise, consist of, or consist essentially of a metal (e.g., titanium, tungsten, cobalt, nickel, platinum, and/or ruthenium), a metal composition (e.g., metal silicide, a metal nitride, such as titanium nitride, and/or a metal carbide), and/or a conductively-doped semiconductor material (e.g., conductively-doped silicon, conductively-doped germanium, and/or conductively-doped gallium arsenide).

The structure 400 may be constructed on and/or supported by a base (not shown). In some implementations, the base is a semiconductor and may comprise, consist of, or consist essentially of semiconductor material. For example, the semiconductor material may comprise, consist of, or consist essentially of silicon, such as monocrystalline silicon. The base is sometimes called a “substrate” or a “semiconductor substrate.” In some implementations, the base may include or may be formed from a semiconductive wafer (either alone or in assemblies comprising other materials) and/or semiconductive material layers (either alone or in assemblies comprising other materials). In some implementations, the base may include one or more materials associated with integrated circuit fabrication, such as one or more refractory metal materials, one or more barrier materials, one or more diffusion materials, and/or one or more insulator materials.

In some implementations, the structure 400 may have a pitch along the x-axis of approximately 24 nanometers or less than 24 nanometers. Thus, a distance from one vertical surface of a pillar 402 to a corresponding vertical surface of a consecutive pillar 402, where there are no pillars between the pillar 402 and the consecutive pillar 402, may be approximately 24 nanometers (or less than 24 nanometers) in the x-direction. In some implementations, the structure 400 may have a pitch along the y-axis of approximately 40 nanometers or less than 40 nanometers. Thus, a distance from one vertical surface of a pillar 402 to a corresponding vertical surface of a consecutive pillar 402, where there are no pillars between the pillar 402 and the consecutive pillar 402, may be approximately 40 nanometers (or less than 40 nanometers) in the y-direction. Thus, where the structure 400 includes an array of pillars 402, a pitch of the array along the first axis (the y-axis) may be greater than a pitch of the array along the third axis (e.g., the x-axis). Example dimensions for the pillar 402, the gate lines 410, the gate dielectrics, and the insulative material 412 are described above in connection with FIG. 2. These dimensions are provided as examples, and these elements may have different dimensions in some implementations.

The structure 400 may be part of an integrated assembly, such as a memory array, a portion of a memory array, or a memory device that includes the memory array. For example, a memory device may include multiple memory cells 100 (e.g., an array of memory cells 100). A memory cell 100 may include a capacitor 110 and a transistor 105. The capacitor 110 may include a bottom electrode 135, a top electrode 140, and an insulator 145 that separates the bottom electrode 135 and the top electrode 140. The transistor 105 may enable access to the capacitor 110 (e.g., a bottom electrode 135 of the capacitor) via a digit line 120, as described above in connection with FIG. 1. The transistor 105 may include the pillar 402 (e.g., the upper source/drain 404, the lower source/drain 406, and the channel 408), a first portion of the first gate line 410a that is proximate to the channel 408 of the pillar 402, and a second portion of the second gate line 410b that is proximate to the channel 408 of the pillar 402. The transistor 105 may selectively couple the digit line 120 and the capacitor 110. For example, the transistor 105 may couple the digit line 120 and the capacitor 110 when the first gate line 410a and the second gate line 410b (that together form an access line 115 for the capacitor 110) are activated. The transistor 105 may decouple the digit line 120 and the capacitor 110 when the first gate line 410a and the second gate line 410b are deactivated. The memory device may include an array with a large quantity of structures 400, pillars 402 (e.g., an array of pillars), and/or memory cells 100 (e.g., hundreds, thousands, millions, or more) that are substantially identical to one another. The structures 400 and/or memory cells 100 may extend across the memory array along the illustrated x-axis and the illustrated y-axis to form a grid pattern or an array pattern.

The term “source/drain” is used for the upper source/drain 404 and the lower source/drain 406 because these regions of the pillar 402 may act as a source at a first time and as a drain at a second (different) time. In a first scenario, when current flows from a digit line 120 to a capacitor 110 situated on top of the structure 400, the lower source/drain 406 is a source, and the upper source/drain 404 is a drain. In a second scenario, when current flows from a capacitor 110 to a digit line 120, the upper source/drain 404 is a source, and the lower source/drain 406 is a drain. Other terminology may be used, such as an “upper pillar region” or an “upper doped region” for the upper source/drain 404 and a “lower pillar region” or a “lower doped region” for the lower source/drain 406.

Each of the illustrated x-axis, y-axis, and z-axis is substantially perpendicular to the other two axes. For example, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As indicated above, FIGS. 4A-4B are provided as examples. Other examples may differ from what is described with respect to FIGS. 4A-4B.

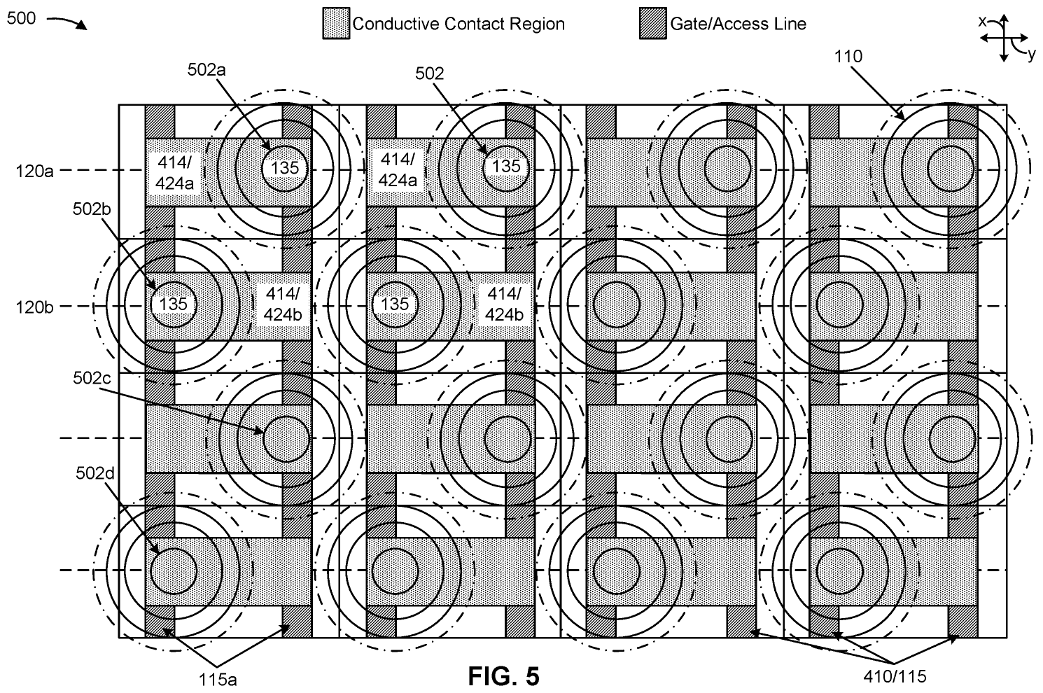

FIG. 5 is a diagrammatic view of an example structure 500 that includes capacitors 110 in contact with the conductive contact region 414 of the structure 400 of FIG. 4. The capacitors 110 each include a bottom electrode 135, an insulator 145, and top electrode 140, as shown and described above in connection with FIG. 3. Furthermore, the capacitors 110 may be separated from one another via respective tolerance regions 305, as shown and described above in connection with FIG. 3. The structure 500 may be part of an integrated assembly, such as a memory array, a portion of a memory array, or a memory device that includes the memory array and one or more other components (e.g., sense amplifiers, a row decoder, a column decoder, a row address buffer, a column address buffer, one or more data buffers, one or more clocks, one or more counters, and/or a memory controller).

As shown in FIG. 5, an electrode pillar 502 is in contact with the conductive contact region 414. For example, a bottom surface of the electrode pillar 502 may abut and/or be in contact with a top surface of the conductive contact region 414. This enables the electrode pillar 502 to be coupled with the pillar 402 (e.g., the transistor pillar 205). In some implementations, an entirety of the bottom surface of the electrode pillar 502 may abut and/or be in contact with a top surface of the conductive contact region 414. This may result in improved electrical and/or conductive properties as compared to only a portion of the bottom surface of the electrode pillar 502 abutting and/or being in contact with a top surface of the conductive contact region 414 (and/or the upper source/drain 404). In some implementations, the electrode pillar 502 is a cylinder, is approximately a cylinder, or is substantially cylindrical in shape. In some implementations, the electrode pillar 502 is a bottom electrode pillar that includes the bottom electrode 135. Thus, the electrode pillar 502 may be a bottom electrode 135 of the capacitor 110. The bottom electrode 135 may be cylindrical in shape and may be referred to as a cylindrical bottom electrode.

As shown in FIG. 5, the structure 500 may include an array of pillars 402 (e.g., underneath the conductive contact regions 414, as is shown in FIGS. 3 and 4B) that are substantially identical to one another. As shown in FIG. 5, a pitch of the array along the illustrated y-axis is greater than a pitch of the array along the illustrated x-axis. As further shown, the structure 500 may include an array of electrode pillars 502 (and corresponding capacitors) that are substantially identical to one another. In other words, a distance between memory cells 100 along a direction parallel to the insulator lines 416 and/or the gate lines 410 (e.g., the x-direction) may be smaller than a distance between memory cells 100 along a direction perpendicular to the insulator lines 416 and/or the gate lines 410 (e.g., the y-direction).

As shown, a set of electrode pillars 502 that are accessible via the same digit line 120 (sometimes called a column of electrode pillars 502) and/or that extend along the first axis (e.g., they-axis) are each in contact with a same portion of a respective conductive contact region 414. For example, each electrode pillar 502 accessible via a first digit line 120a shown in FIG. 5 is in contact with a respective second conductive region 424b (e.g., a right portion of the top surface of the conductive contact region 414, as shown). As another example, each electrode pillar 502 accessible via a second digit line 120b shown in FIG. 5 is in contact with a respective first conductive region 424a (e.g., a left portion of the top surface of the conductive contact region 414, as shown).

As shown, a set of electrode pillars 502 that are accessible via the same access line 115 and/or the same pair of gate lines 410 (sometimes called a row of electrode pillars 502) and/or that extend along the third axis (e.g., the x-axis) are not each in contact with a same portion of a respective conductive contact region 414. Instead, alternating electrode pillars, included in this set of electrode pillars 502, are in contact with alternating ones of the first conductive region 424a and the second conductive region 424b. For example, electrode pillars 502a, 502b, 502c, and 502d are accessible via a first access line 115a shown in FIG. 5. Electrode pillar 502a and electrode pillar 502b are alternating (or consecutive) electrode pillars, electrode pillar 502b and electrode pillar 502c are alternating (or consecutive) electrode pillars, and electrode pillar 502c and electrode pillar 502d are alternating (or consecutive) electrode pillars. As shown, electrode pillar 502a is in contact with a second conductive contact region 424b of a corresponding conductive contact region 414, electrode pillar 502b is in contact with a first conductive contact region 424a of a corresponding conductive contact region 414, electrode pillar 502c is in contact with a second conductive contact region 424b of a corresponding conductive contact region 414, and electrode pillar 502d is in contact with a first conductive contact region 424a of a corresponding conductive contact region 414.

As indicated above, FIG. 5 is provided as an example. Other examples may differ from what is described with respect to FIG. 5.

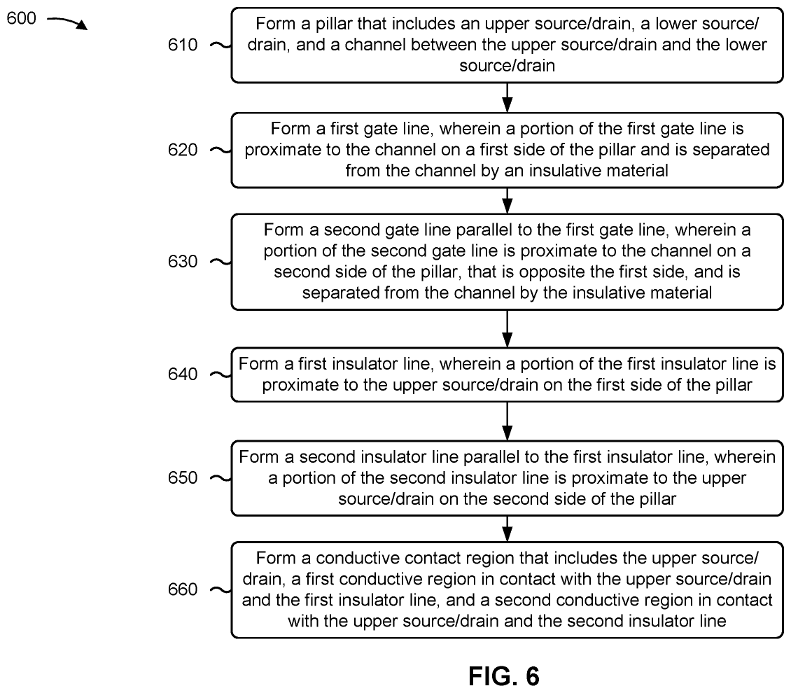

FIG. 6 is a flowchart of an example method 600 of forming an integrated assembly or memory device having a redistribution layer between transistors and capacitors. In some implementations, one or more process blocks of FIG. 6 may be performed by various semiconductor manufacturing equipment.

As shown in FIG. 6, the method 600 may include forming a pillar that includes an upper source/drain, a lower source/drain, and a channel between the upper source/drain and the lower source/drain (block 610). As further shown in FIG. 6, the method 600 may include forming a first gate line, wherein a portion of the first gate line is proximate to the channel on a first side of the pillar and is separated from the channel by an insulative material (block 620). As further shown in FIG. 6, the method 600 may include forming a second gate line parallel to the first gate line, wherein a portion of the second gate line is proximate to the channel on a second side of the pillar, that is opposite the first side, and is separated from the channel by the insulative material (block 630). As further shown in FIG. 6, the method 600 may include forming a first insulator line, wherein a portion of the first insulator line is proximate to the upper source/drain on the first side of the pillar (block 640). As further shown in FIG. 6, the method 600 may include forming a second insulator line parallel to the first insulator line, wherein a portion of the second insulator line is proximate to the upper source/drain on the second side of the pillar (block 650). As further shown in FIG. 6, the method 600 may include forming a conductive contact region that includes the upper source/drain, a first conductive region in contact with the upper source/drain and the first insulator line, and a second conductive region in contact with the upper source/drain and the second insulator line (block 660).

In some implementations, the method 600 may include forming an insulative spacer region that comprises the insulative material, wherein the insulative spacer region abuts the first insulator line and the second insulator line and separates the conductive contact region from an adjacent conductive contact region associated with an adjacent pillar. In some implementations, the conductive contact region is centered over the channel or the upper source/drain. In some implementations, the method 600 may include forming a capacitor that includes a top electrode, an insulator, and a cylindrical bottom electrode, wherein the cylindrical bottom electrode is in contact with the conductive contact region.

Although FIG. 6 shows example blocks of the method 600, in some implementations, the method 600 may include additional blocks, fewer blocks, different blocks, or differently arranged blocks than those depicted in FIG. 6. In some implementations, the method 600 may include forming the structure 400 and/or the structure 500, an integrated assembly that includes the structure 400 and/or the structure 500, any part described herein of the structure 400 and/or the structure 500, and/or any part described herein of an integrated assembly that includes the structure 400 and/or the structure 500. For example, the method 600 may include forming one or more of the parts 105-150, 205-215, 402-424, and/or 502.

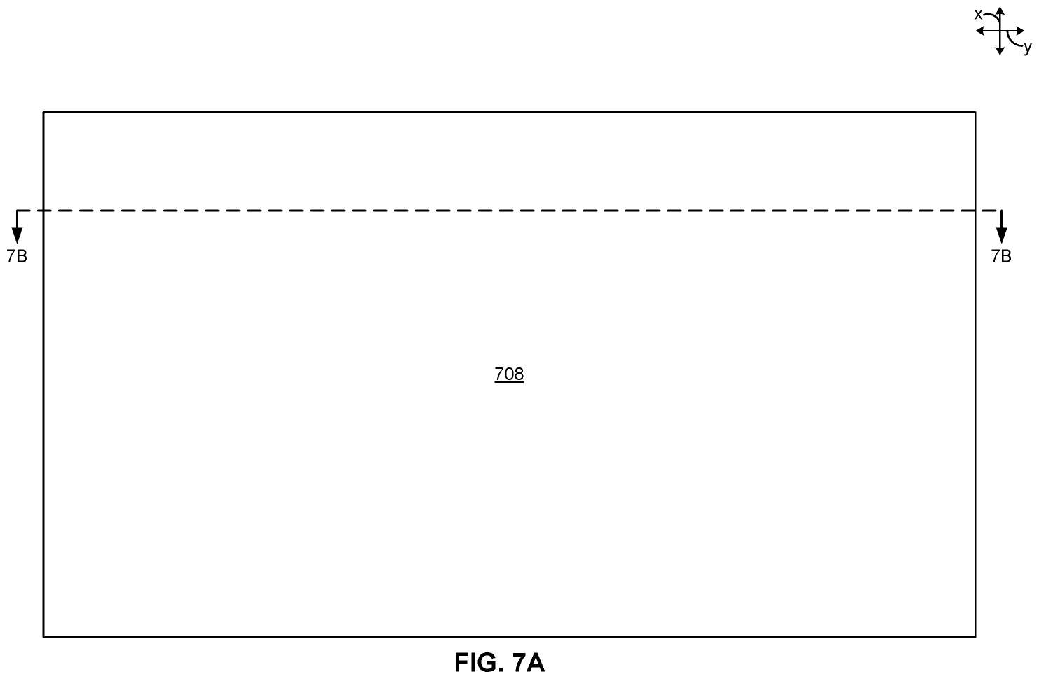

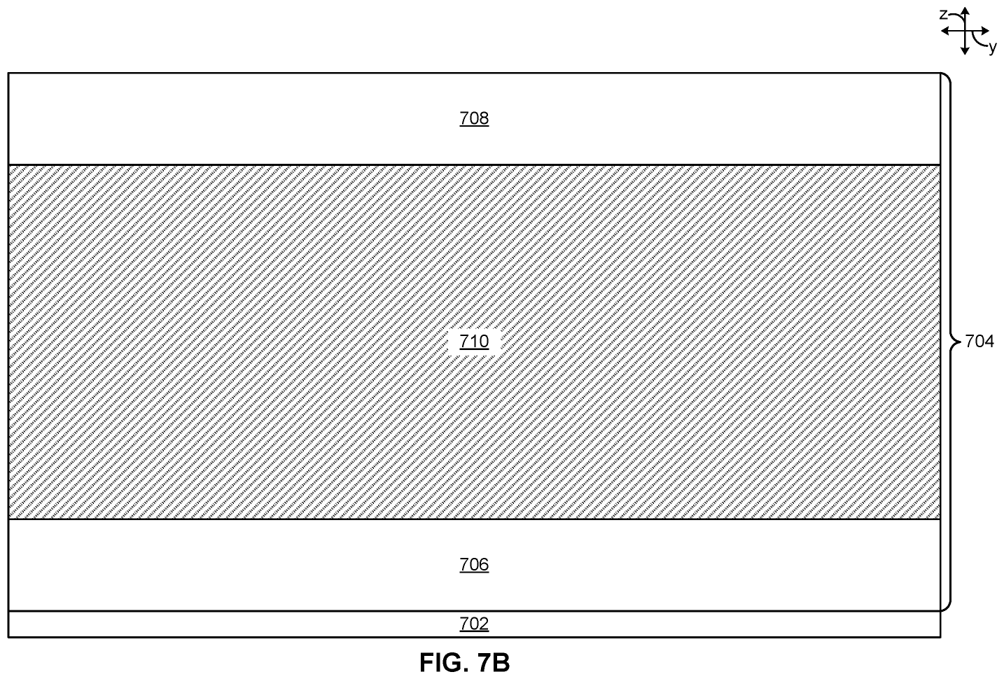

FIGS. 7A-7B through 15A-15B are diagrammatic views showing formation of the structure 400 at example process stages of an example process of forming the structure 400. In some implementations, the example process described below in connection with FIGS. 7A-7B through 15A-15B may correspond to the method 600 and/or one or more blocks of the method 600. However, the process described below is an example, and other example processes may be used to form the structure 400, an integrated assembly that includes the structure 400, and/or one or more parts of the structure 400 and/or the integrated assembly.

As shown in FIGS. 7A-7B, the process may include forming (e.g., depositing or growing) material 702 on a substrate (not shown). The material 702 may form the digit lines 120 and may comprise, consist of, or consist essentially of one or more of the materials described above in connection with the digit lines 120.

As further shown in FIGS. 7A-7B, the process may include forming (e.g., depositing or growing) material 704 on the material 702. The material 704 may form the pillars 402 and may comprise, consist of, or consist essentially of one or more of the materials described above in connection with the pillars 402.

As further shown in FIGS. 7A-7B, the process may include doping the material 704 to form a first doped region 706 and a second doped region 708. The first doped region 706 may form the lower source/drain 406 and may comprise, consist of, or consist essentially of one or more of the materials described above in connection with the lower source/drain 406. The second doped region 708 may form the upper source/drain 404 and may comprise, consist of, or consist essentially of one or more of the materials described above in connection with the upper source/drain 404. The doping process may also form a channel region 710. The channel region 710 may form the channel 408 and may comprise, consist of, or consist essentially of one or more of the materials described above in connection with the channel 408. The channel region 710 may be undoped or may be lightly doped (e.g., as compared to the first doped region 706 and the second doped region 708). In some implementations, the material 704 may be doped using ion implantation. Alternatively, the material 704 may be doped using in situ doping, such that the material 704 is doped as the material 704 is being formed (e.g., grown or deposited).

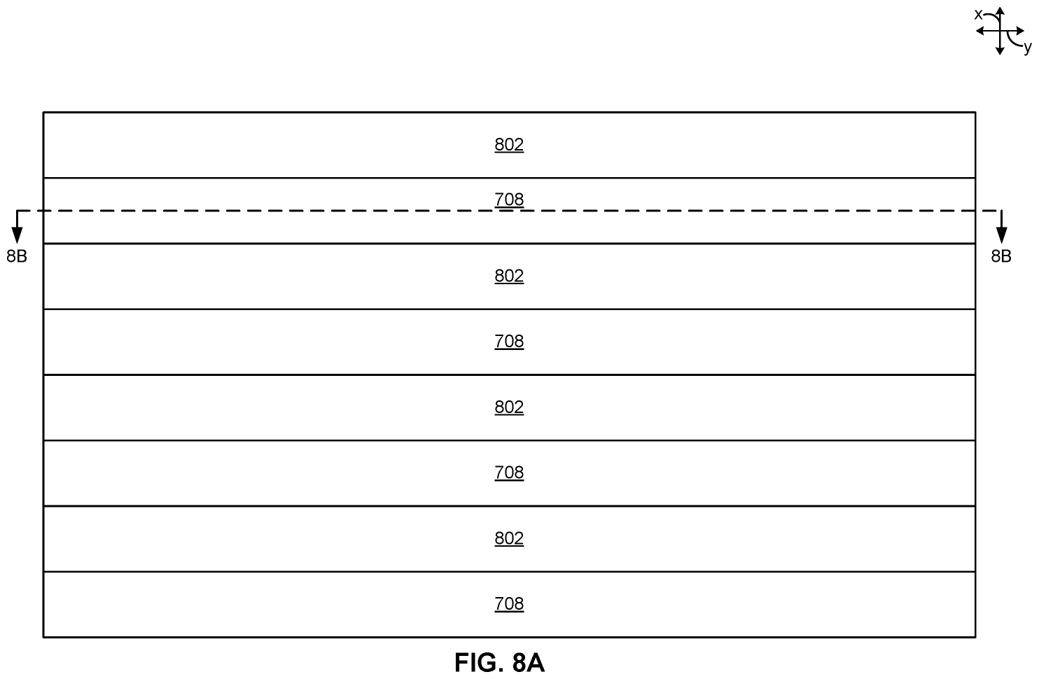

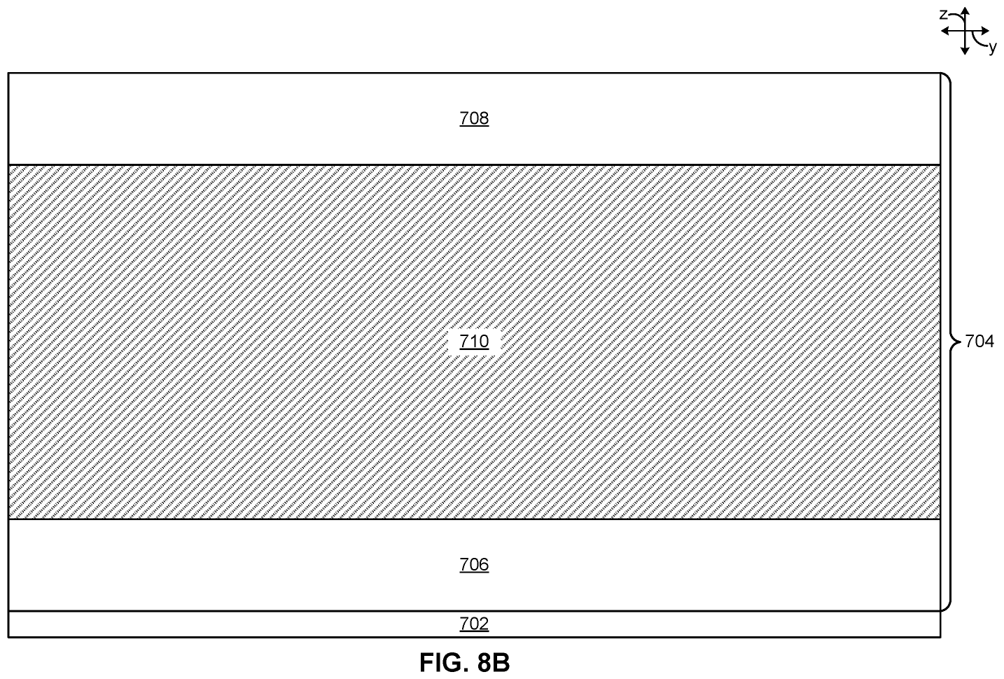

As shown in FIGS. 8A-8B, the process may include removing (e.g., etching) a portion of the material 702 and the material 704 to form trenches 802. The trenches 802 may extend in the y-direction across the integrated assembly. The removal may be full stack removal (e.g., a full stack etch) to remove all material except for the substrate (not shown) along the trenches 802. This process step results in the digit lines 120 (e.g., separated by the trenches 802). In some implementations, one or more masks may be used to from the trenches 802. For example, one or more masks may be deposited and/or patterned on the material 704 prior to removing material to form the trenches 802.

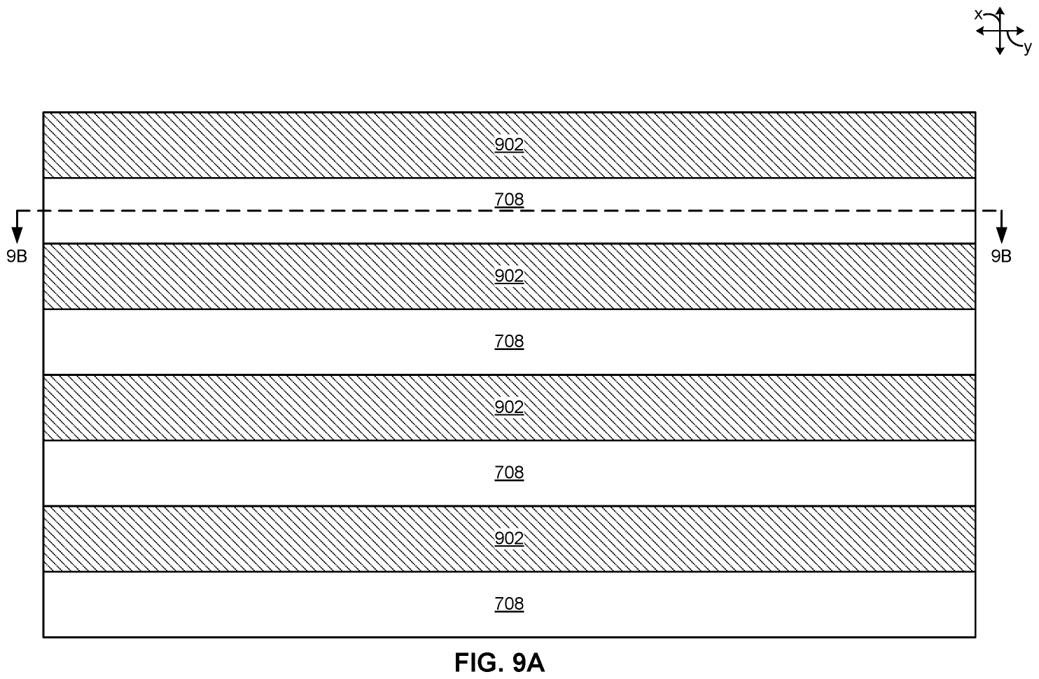

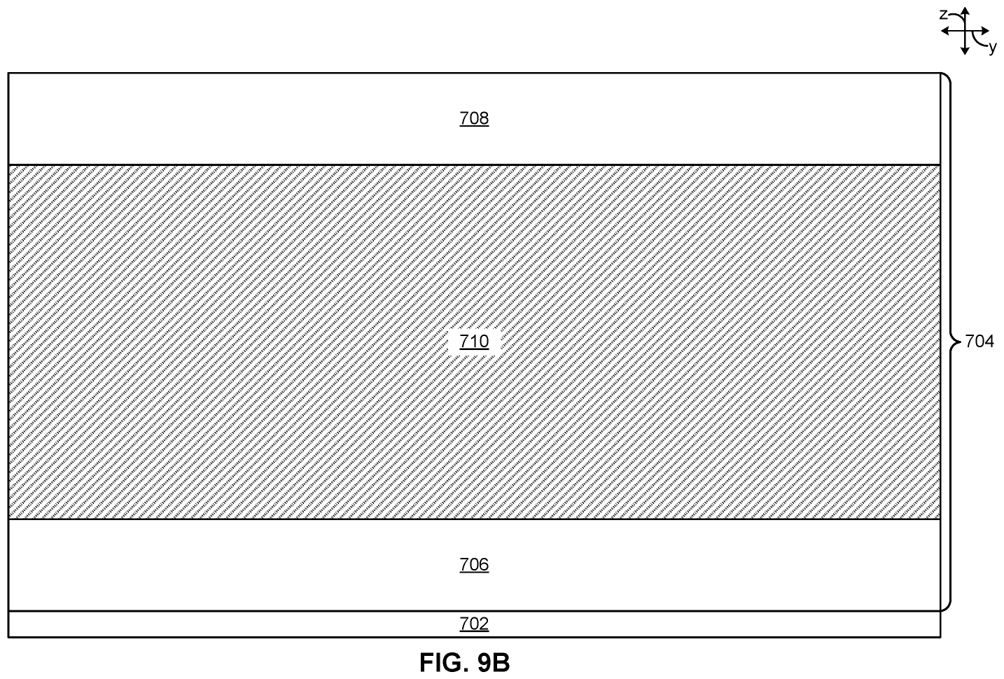

As shown in FIGS. 9A-9B, the process may include forming (e.g., depositing or growing) material 902 in the trenches 802. The material 902 may form a portion of the insulative material 412, may form a portion of the spacer regions 418, and may comprise, consist of, or consist essentially of one or more of the materials described above in connection with the insulative material 412 and/or the spacer regions 418. In some implementations, the material 902 may fill the trenches 802 such that a top surface of the material 902 is substantially horizontally aligned with a top surface of the material 704. In some implementations, the process may include planarizing a horizontal surface of the integrated assembly to achieve this alignment.

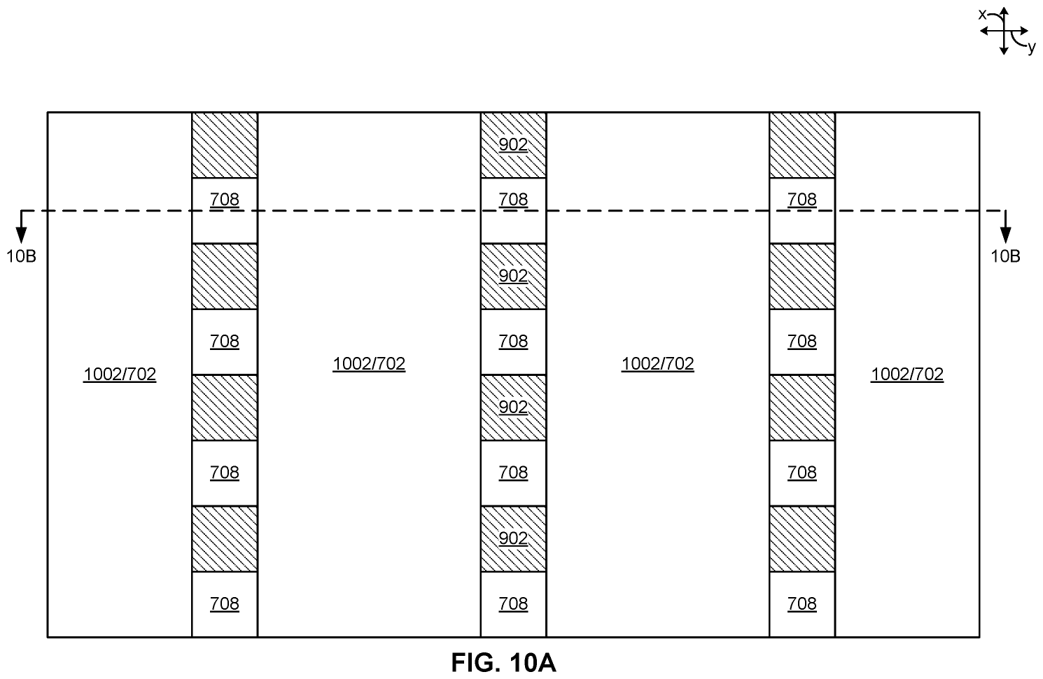

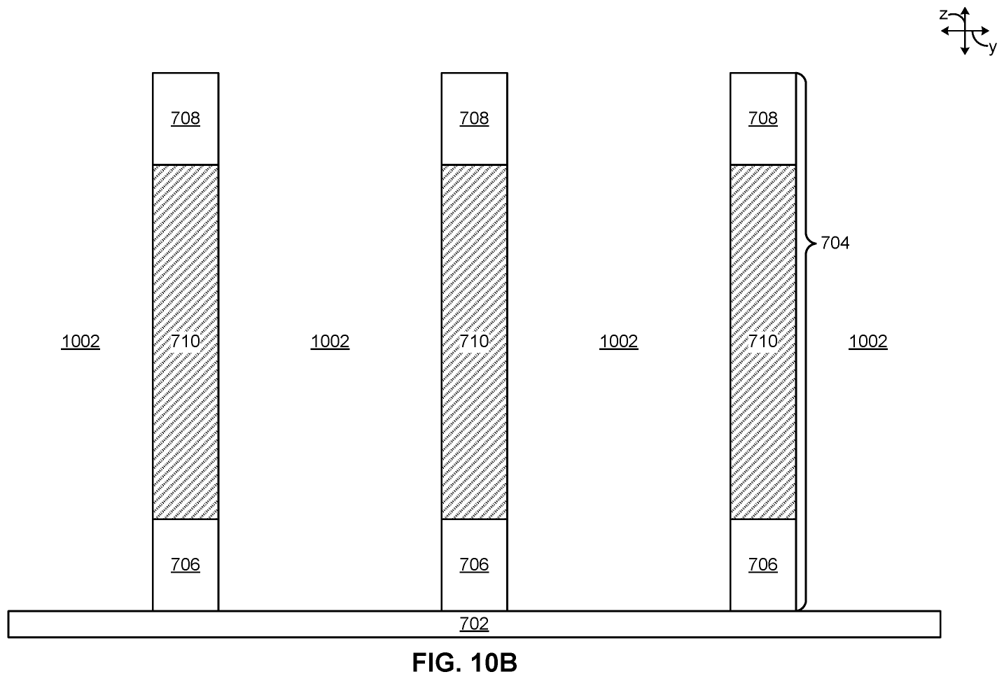

As shown in FIGS. 10A-10B, the process may include removing (e.g., etching) a portion of the material 704 to form trenches 1002. The trenches 1002 may extend in the x-direction across the integrated assembly. The removal may remove all material in the stack along the trenches 1002 down to the material 702. In some implementations, one or more masks may be used to from the trenches 1002. For example, one or more masks may be deposited and/or patterned on the second doped region 708 and/or the material 902 prior to removing material to form the trenches 1002.

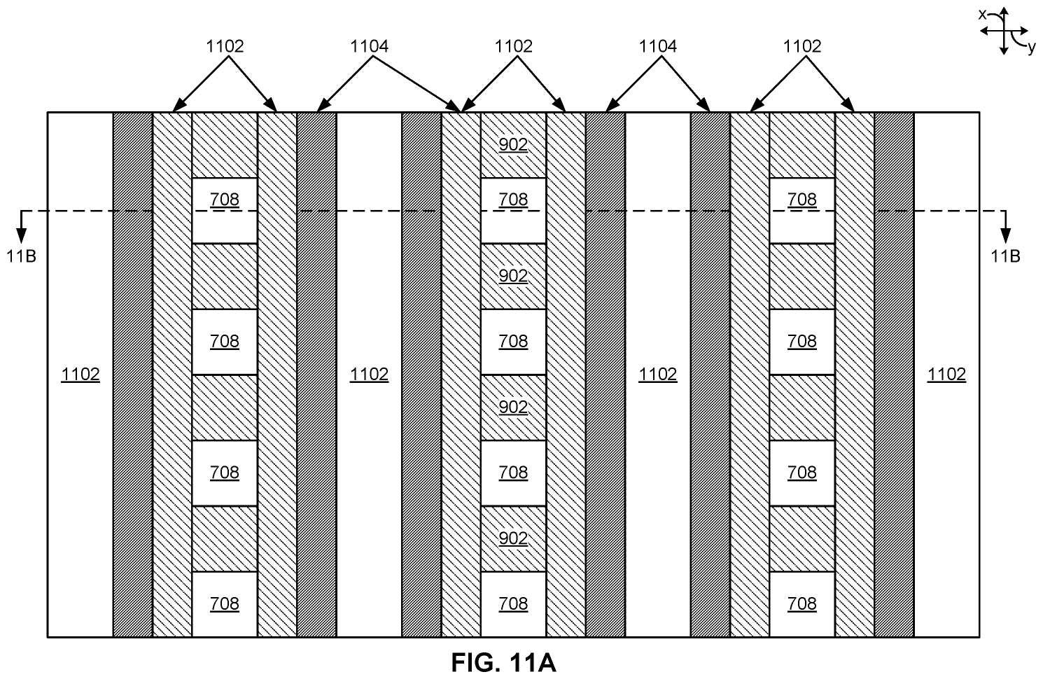

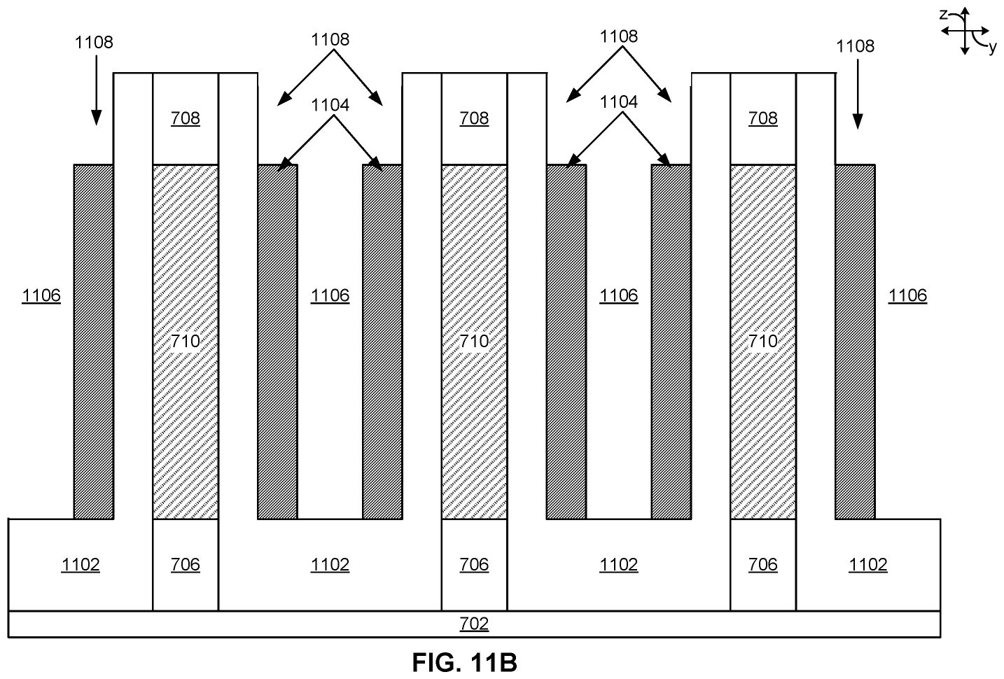

As shown in FIGS. 11A-11B, the process may include forming (e.g., depositing or growing) material 1102 on the material 702 and the material 704 (e.g., the first doped region 706, the second doped region 708, and the channel region 710). For example, the material 1102 may fill a portion of the trenches 1002 along surfaces of the material 702 and the material 704 that line the trenches 1002. The material 1102 may form a portion of the insulative material 412, may form a portion of the spacer regions 418, and may comprise, consist of, or consist essentially of one or more of the materials described above in connection with the insulative material 412 and/or the spacer regions 418.

As further shown in FIGS. 11A-11B, the process may include forming (e.g., depositing or growing) material 1104 on the material 1102. In some implementations, the material 1104 may fill a portion of the trenches 1002 along surfaces of the material 1102 that line the trenches 1002, leaving trenches 1106. The trenches 1106 may extend in the x-direction across the integrated assembly. In some implementations, the material 1104 may completely fill a portion of the trenches 1002 that are not filled by the material 1102. In this case, the process may include removing (e.g., etching) a portion of the material 1104 to form the trenches 1106 and/or to form recessed regions 1108 directly above the material 1104 and extending in the x-direction across the integrated assembly. The material 1104 may form the gate lines 410 and may comprise, consist of, or consist essentially of one or more of the materials described above in connection with the gate lines 410.

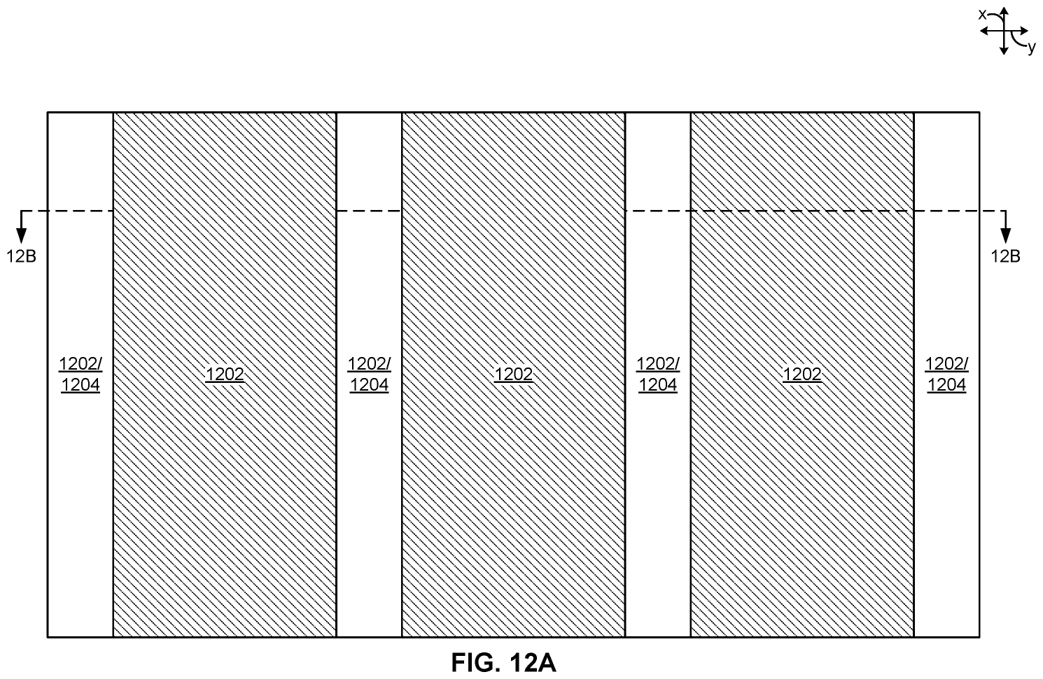

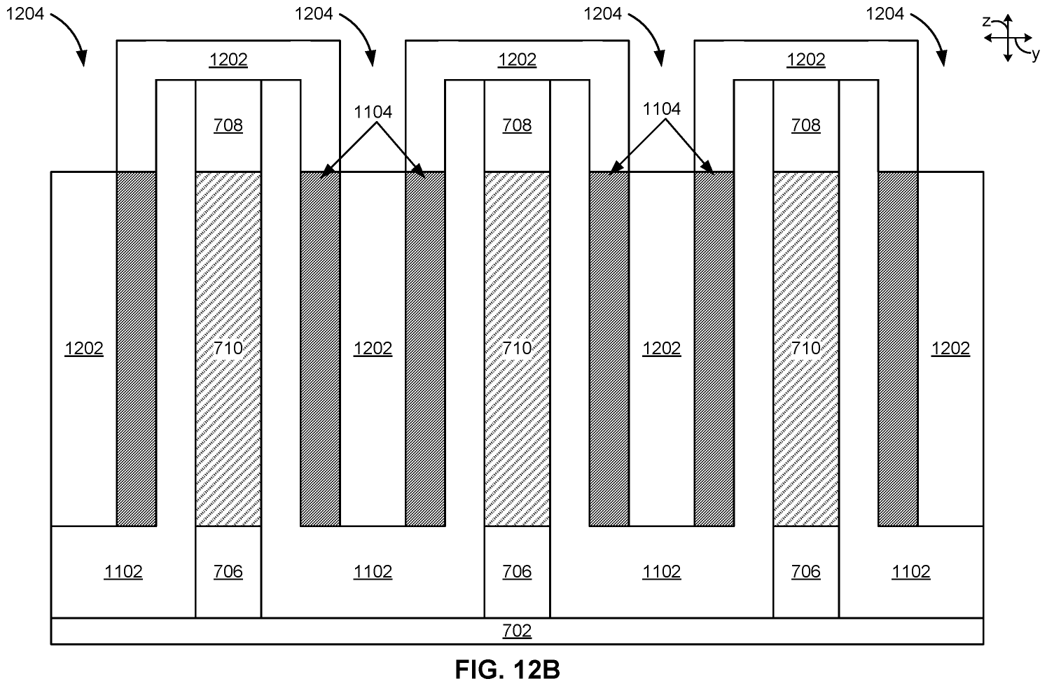

As shown in FIGS. 12A-12B, the process may include forming (e.g., depositing or growing) material 1202 on the material 1102, the material 1104, and the material 704 (e.g., the second doped region 708). For example, the material 1202 may fill the trenches 1106. Furthermore, the material 1202 may fill the recessed regions 1108 directly above the material 1104 to leave trenches 1204 between an area above the material 1104 (e.g., between an area above the gate lines 410), leaving trenches 1204. The trenches 1204 may extend in the x-direction across the integrated assembly. In some implementations, the material 1202 may completely fill the region between the material 704 (e.g., between pillars 402). In this case, the process may include removing (e.g., etching) a portion of the material 1202 to form the trenches 1204. The material 1202 may form a portion of the insulative material 412, may form a portion of the spacer regions 418, and may comprise, consist of, or consist essentially of one or more of the materials described above in connection with the insulative material 412 and/or the spacer regions 418.

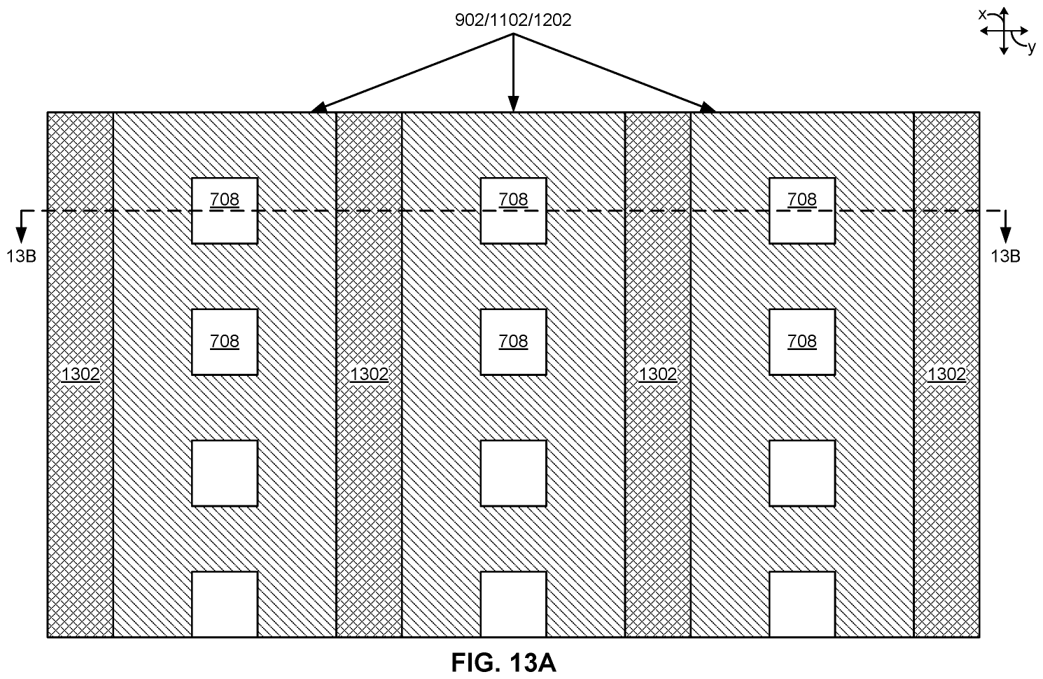

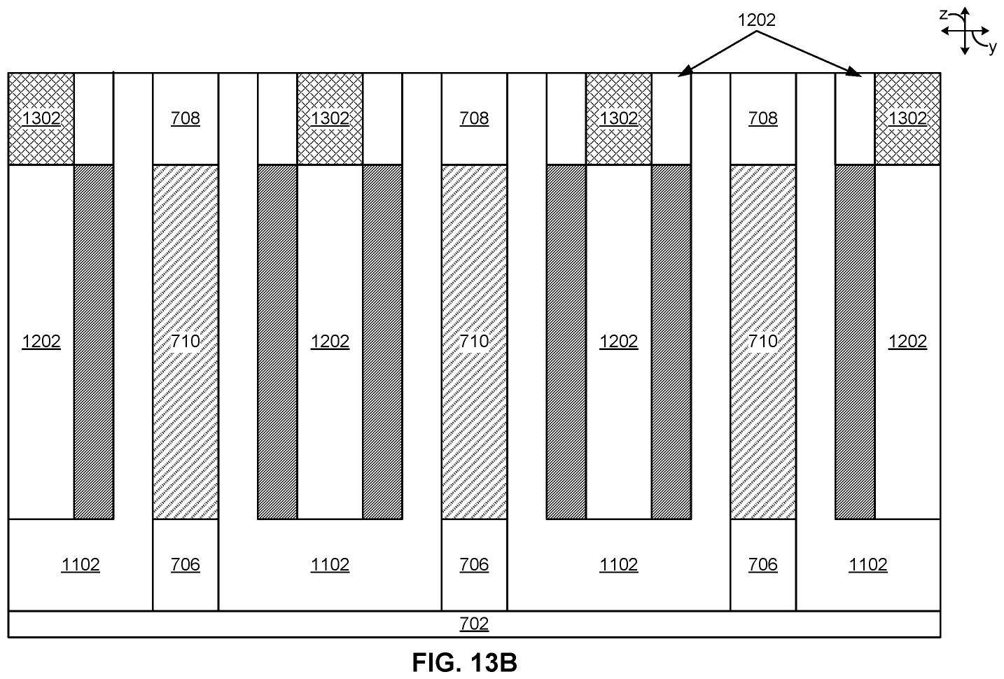

As shown in FIGS. 13A-13B, the process may include forming (e.g., depositing or growing) material 1302 in the trenches 1204. The material 1302 may form the insulator lines 416 and may comprise, consist of, or consist essentially of one or more of the materials described above in connection with the insulator lines 416. In some implementations, the process may include planarizing a horizontal surface of the integrated assembly to horizontally align respective top surfaces of the second doped region 708, the material 1102, the material 1202, and the material 1302.

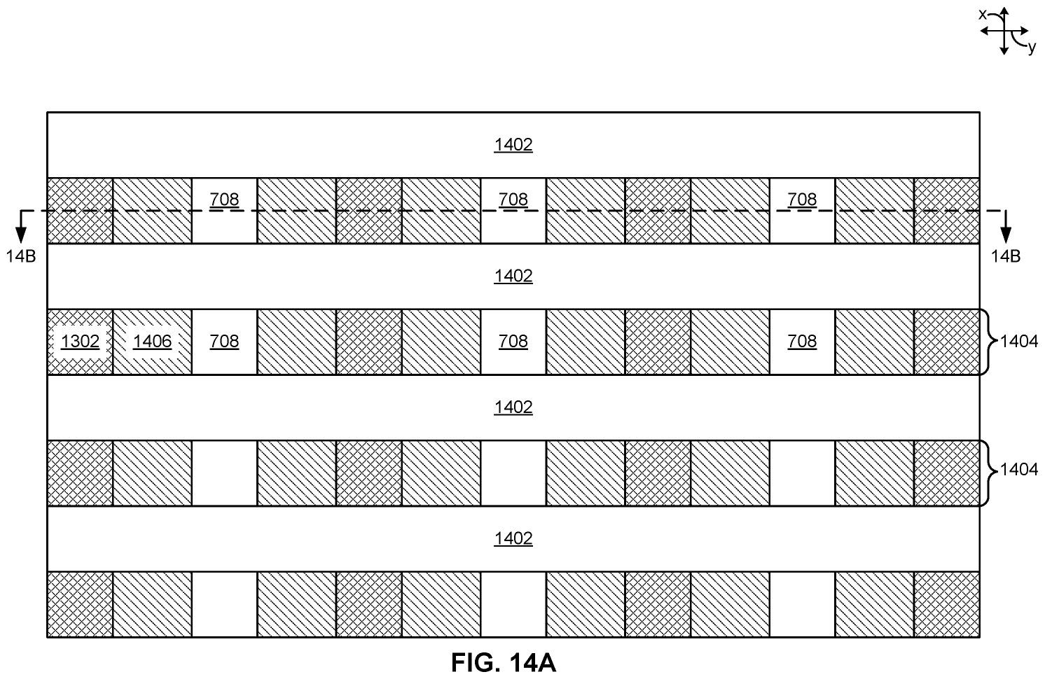

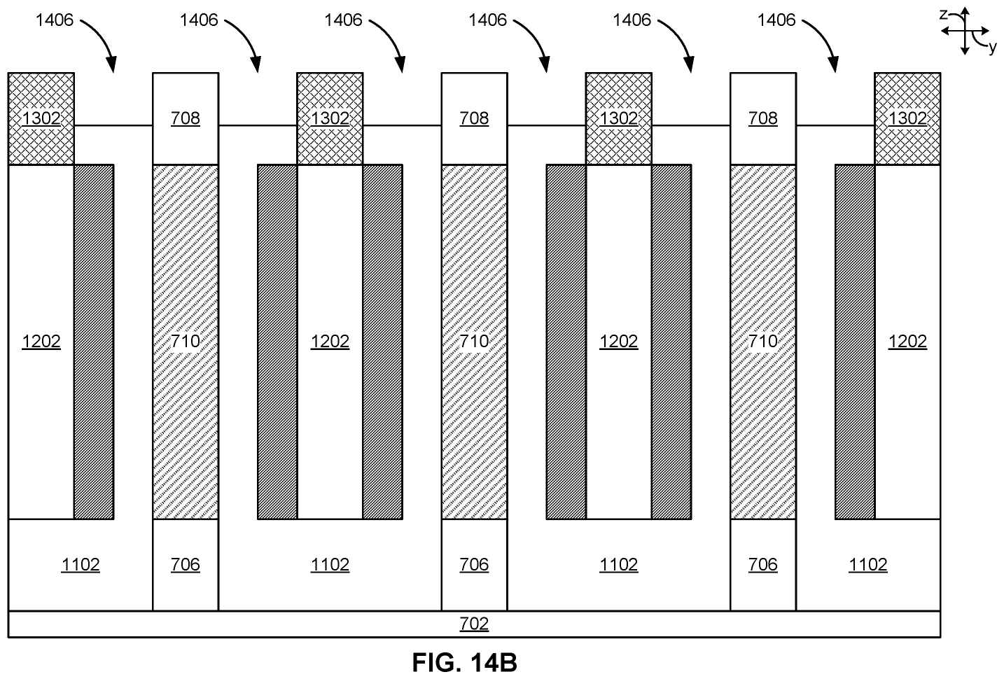

As shown in FIGS. 14A-14B, the process may include forming (e.g., depositing or growing) a mask 1402 on the material 902/1102/1202 (e.g., the insulative material 412) and the material 1302 (e.g., the spacer regions 418). The mask 1402 may extend along the y-direction and may leave trenches 1404 that extend along the y-direction and that leave the material 704 (e.g., the second doped region 708) exposed. The mask 1402 may comprise, consist of, or consist essentially of a photoresist material, among other examples.

As further shown in FIGS. 14A-14B, the process may include removing (e.g., etching) a portion of insulative material (e.g., material 1102, material 1202, and/or insulative material 412) in an unmasked region along the trenches 1404 to form recessed regions 1406. In some implementations, the removal process removes silicon oxide of the insulative material 412, does not remove silicon nitride of the insulator line 416, and does not remove doped semiconductor material of the upper source/drain 404. In some implementations, the mask 1402 is removed after forming the recessed regions 1406.

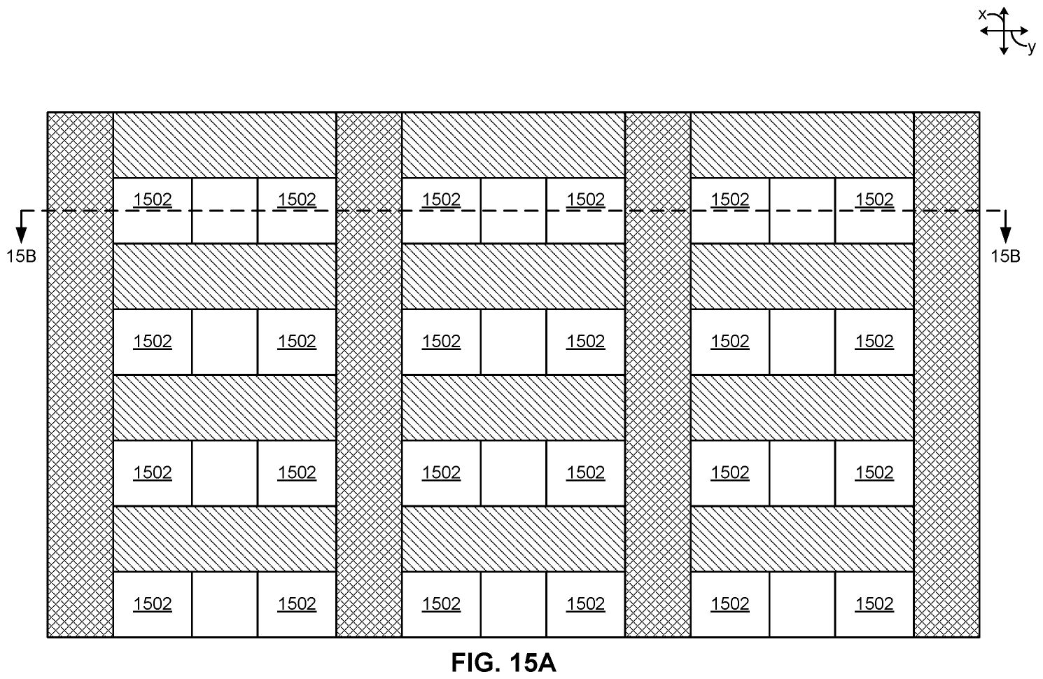

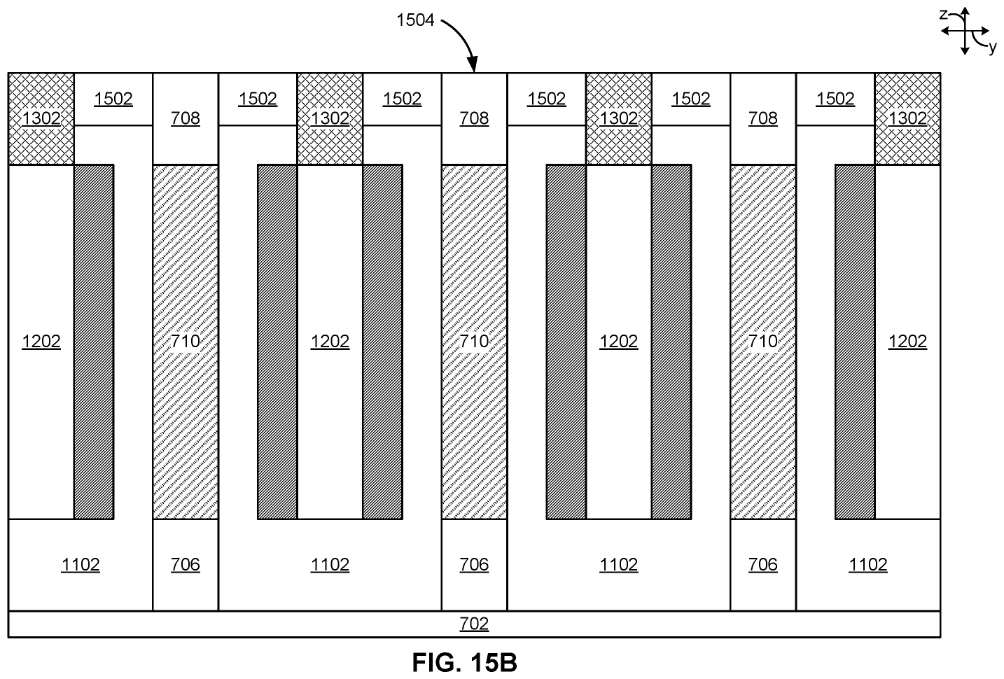

As shown in FIGS. 15A-15B, the process may include forming (e.g., depositing or growing) material 1502 in the recessed regions 1406. The material 1502 may form the conductive regions 424 (e.g., the first conductive regions 424a and the second conductive regions 424b) and may comprise, consist of, or consist essentially of one or more of the materials described above in connection with the conductive regions 424. The material 1502 and the second doped region 708 (or a portion thereof) may form the conductive contact region 414. In some implementations, the process may include planarizing a top surface 1504 of the integrated assembly. For example, the top surface 1504 may be planarized using chemical-mechanical polishing or another suitable planarization technique.

The structure shown in FIGS. 15A-15B may be equivalent to the structure 400 described elsewhere herein. In some implementations, the process may include forming one or more electrical components on top of the top surface 1504 and in contact with the conductive contact region 414 (e.g., the material 1502 and/or the second doped region 708). For example, the process may include forming an electrode, an electrode pillar, a bottom electrode, and/or a capacitor in contact with the conductive contact region 414, as described elsewhere herein (e.g., to form the structure 500).

As indicated above, the process steps described in connection with FIGS. 7A-7B through 15A-15B are provided as examples. Other examples may differ from what is described with respect to FIGS. 7A-7B through 15A-15B. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

FIG. 16 is a diagrammatic view of an example memory device 1600. The memory device 1600 may include a memory array 1602 that includes multiple memory cells 1604. A memory cell 1604 is programmable or configurable into a data state of multiple data states (e.g., two or more data states). For example, a memory cell 1604 may be set to a particular data state at a particular time, and the memory cell 1604 may be set to another data state at another time. A data state may correspond to a value stored by the memory cell 1604. The value may be a binary value, such as a binary 0 or a binary 1, or may be a fractional value, such as 0.5, 1.5, or the like. A memory cell 1604 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so son.

Operations such as reading and writing (i.e., cycling) may be performed on memory cells 1604 by activating or selecting the appropriate access line 1606 (shown as access lines AL 1 through AL M) and digit line 1608 (shown as digit lines DL 1 through DL N). An access line 1606 may also be referred to as a “row line” or a “word line,” and a digit line 1608 may also be referred to a “column line” or a “bit line.” Activating or selecting an access line 1606 or a digit line 1608 may include applying a voltage to the respective line. An access line 1606 and/or a digit line 1608 may comprise, consist of, or consist essentially of a conductive material, such as a metal (e.g., copper, aluminum, gold, titanium, or tungsten) and/or a metal alloy, among other examples. In FIG. 16, each row of memory cells 1604 is connected to a single access line 1606, and each column of memory cells 1604 is connected to a single digit line 1608. By activating one access line 1606 and one digit line 1608 (e.g., applying a voltage to the access line 1606 and digit line 1608), a single memory cell 1604 may be accessed at (e.g., is accessible via) the intersection of the access line 1606 and the digit line 1608. The intersection of the access line 1606 and the digit line 1608 may be called an “address” of a memory cell 1604.

In some implementations, the logic storing device of a memory cell 1604, such as a capacitor, may be electrically isolated from a corresponding digit line 1608 by a selection component, such as a transistor. The access line 1606 may be connected to and may control the selection component. For example, the selection component may be a transistor, and the access line 1606 may be connected to the gate of the transistor. Activating the access line 1606 results in an electrical connection or closed circuit between the capacitor of a memory cell 1604 and a corresponding digit line 1608. The digit line 1608 may then be accessed (e.g., is accessible) to either read from or write to the memory cell 1604.

A row decoder 1610 and a column decoder 1612 may control access to memory cells 1604. For example, the row decoder 1610 may receive a row address from a memory controller 1614 and may activate the appropriate access line 1606 based on the received row address. Similarly, the column decoder 1612 may receive a column address from the memory controller 1614 and may activate the appropriate digit line 1608 based on the column address.

Upon accessing a memory cell 1604, the memory cell 1604 may be read (e.g., sensed) by a sense component 1616 to determine the stored data state of the memory cell 1604. For example, after accessing the memory cell 1604, the capacitor of the memory cell 1604 may discharge onto its corresponding digit line 1608. Discharging the capacitor may be based on biasing, or applying a voltage, to the capacitor. The discharging may induce a change in the voltage of the digit line 1608, which the sense component 1616 may compare to a reference voltage (not shown) to determine the stored data state of the memory cell 1604. For example, if the digit line 1608 has a higher voltage than the reference voltage, then the sense component 1616 may determine that the stored data state of the memory cell 1604 corresponds to a first value, such as a binary 1. Conversely, if the digit line 1608 has a lower voltage than the reference voltage, then the sense component 1616 may determine that the stored data state of the memory cell 1604 corresponds to a second value, such as a binary 0. The detected data state of the memory cell 1604 may then be output (e.g., via the column decoder 1612) to an output component 1618 (e.g., a data buffer). A memory cell 1604 may be written (e.g., set) by activating the appropriate access line 1606 and digit line 1608. The column decoder 1612 may receive data, such as input from input component 1620, to be written to one or more memory cells 1604. A memory cell 1604 may be written by applying a voltage across the capacitor of the memory cell 1604.

The memory controller 1614 may control the operation (e.g., read, write, re-write, refresh, and/or recovery) of the memory cells 1604 via the row decoder 1610, the column decoder 1612, and/or the sense component 1616. The memory controller 1614 may generate row address signals and column address signals to activate the desired access line 1606 and digit line 1608. The memory controller 1614 may also generate and control various voltages used during the operation of the memory array 1602.

In some implementations, the memory device 1600 includes the structure 400 and/or the structure 500. Additionally, or alternatively, the memory device 1600 may include an integrated assembly that includes the structure 400 and/or the structure 400. For example, the memory array 1602 may include the structure 400 and/or the structure 500. Additionally, or alternatively, the memory array 1602 may include an integrated assembly that includes the structure 400 and/or the structure 500. Additionally, or alternatively, the memory cell 1604 may include a memory cell described elsewhere herein.

As indicated above, FIG. 16 is provided as an example. Other examples may differ from what is described with respect to FIG. 16.

In some implementations, an integrated assembly includes a pillar that includes an upper source/drain, a lower source/drain, a channel between the upper source/drain and the lower source/drain, a left-facing vertical surface facing a first direction along a first axis, and a right-facing vertical surface facing a second direction that is opposite the first direction along the first axis, wherein the pillar extends vertically along a second axis that is perpendicular to the first axis; a first conductor line that extends along the first axis from the upper source/drain to a first insulator line that extends along a third axis that is perpendicular to a plane formed by the first axis and the second axis, wherein the left-facing vertical surface faces a portion of the first insulator line that contacts the first conductor line; a second conductor line that extends along the first axis from the upper source/drain to a second insulator line that is parallel to the first insulator line, wherein the right-facing vertical surface faces a portion of the second insulator line that contacts the second conductor line; a first gate line that extends in a same direction as the first insulator line and the second insulator line, wherein the left-facing vertical surface faces a portion of the first gate line that is proximate to the channel; a second gate line that extends in a same direction as the first insulator line and the second insulator line, wherein the right-facing vertical surface faces a portion of the second gate line that is proximate to the channel; and an electrode pillar that is in contact with a conductive contact region formed by the first conductor line, the second conductor line, and the upper source/drain.

In some implementations, a memory device includes an array of memory cells that each include: a transistor, comprising: a pillar that includes an upper source/drain, a lower source/drain, and a channel between the upper source/drain and the lower source/drain, one or more gates that are part of one or more gate lines and that are proximate to the channel; a capacitor, comprising: a bottom electrode, an insulator, and a top electrode; and a conductive contact region that couples the transistor and the capacitor, comprising: the upper source/drain, a first conductive region having a right surface that abuts the upper source/drain and having a left surface that contacts a first insulator line, and a second conductive region having a left surface that abuts the upper source/drain and having a right surface that contacts a second insulator line that is parallel to the first insulator line.

In some implementations, a method includes forming a pillar that includes an upper source/drain, a lower source/drain, and a channel between the upper source/drain and the lower source/drain; forming a first gate line, wherein a portion of the first gate line is proximate to the channel on a first side of the pillar and is separated from the channel by an insulative material; forming a second gate line parallel to the first gate line, wherein a portion of the second gate line is proximate to the channel on a second side of the pillar, that is opposite the first side, and is separated from the channel by the insulative material; forming a first insulator line, wherein a portion of the first insulator line is proximate to the upper source/drain on the first side of the pillar; forming a second insulator line parallel to the first insulator line, wherein a portion of the second insulator line is proximate to the upper source/drain on the second side of the pillar; and forming a conductive contact region that includes the upper source/drain, a first conductive region in contact with the upper source/drain and the first insulator line, and a second conductive region in contact with the upper source/drain and the second insulator line.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a pillar that includes an upper source/drain, a lower source/drain, a channel between the upper source/drain and the lower source/drain, a left-facing vertical surface facing a first direction along a first axis, and a right-facing vertical surface facing a second direction that is opposite the first direction along the first axis,
wherein the pillar extends vertically along a second axis that is perpendicular to the first axis;
a first conductor line that extends along the first axis from the upper source/drain to a first insulator line that extends along a third axis that is perpendicular to a plane formed by the first axis and the second axis,
wherein the left-facing vertical surface faces a portion of the first insulator line that contacts the first conductor line;
a second conductor line that extends along the first axis from the upper source/drain to a second insulator line that is parallel to the first insulator line,
wherein the right-facing vertical surface faces a portion of the second insulator line that contacts the second conductor line;
a first gate line that extends in a same direction as the first insulator line and the second insulator line,
wherein the left-facing vertical surface faces a portion of the first gate line that is proximate to the channel;
a second gate line that extends in a same direction as the first insulator line and the second insulator line,
wherein the right-facing vertical surface faces a portion of the second gate line that is proximate to the channel; and
an electrode pillar that is in contact with a conductive contact region formed by the first conductor line, the second conductor line, and the upper source/drain.

2. The integrated assembly of claim 1, wherein the pillar is a rectangular prism and the electrode pillar is a cylinder.

3. The integrated assembly of claim 1, further comprising an array of pillars, including the pillar, that are substantially identical,
wherein a pitch of the array along the first axis is greater than a pitch of the array along the third axis.

4. The integrated assembly of claim 1, further comprising:
an array of pillars, including the pillar, that are substantially identical, and
an array of electrode pillars, including the electrode pillar, that are substantially identical,
wherein each electrode pillar, included in a first set of electrode pillars accessible via a first digit line, is in contact with a respective first conductor line.

5. The integrated assembly of claim 4, wherein each electrode pillar, included in a second set of electrode pillars accessible via a second digit line and adjacent to the first set of electrode pillars, is in contact with a respective second conductor line.

6. The integrated assembly of claim 1, further comprising:
an array of pillars, including the pillar, that are substantially identical, and
an array of electrode pillars, including the electrode pillar, that are substantially identical,
wherein alternating electrode pillars, included in a set of electrode pillars that extends along the third axis, are in contact with alternating ones of the first conductor line and the second conductor line.

7. The integrated assembly of claim 1, wherein the pillar, the portion of the first gate line that is proximate to the channel, and the portion of the second gate line that is proximate to the channel form a transistor,
wherein the electrode pillar is a bottom electrode of a capacitor that includes the bottom electrode, an insulator, and a top electrode, and
further comprising a digit line that is beneath the pillar, is electrically coupled with the lower source/drain, and is parallel to the first conductor line and the second conductor line,
wherein the transistor selectively couples the capacitor and the digit line.

8. The integrated assembly of claim 1, wherein a top surface of the conductive contact region is rectangular.

9. A memory device, comprising:
an array of memory cells that each include:
a transistor, comprising:
a pillar that includes an upper source/drain, a lower source/drain,
and a channel between the upper source/drain and the lower source/drain,
one or more gates that are part of one or more gate lines and that are proximate to the channel;
a capacitor, comprising:
a bottom electrode, an insulator, and a top electrode; and
a conductive contact region that couples the transistor and the capacitor, comprising:
the upper source/drain,
a first conductive region having a right surface that abuts the upper source/drain and having a left surface that contacts a first insulator line, and
a second conductive region having a left surface that abuts the upper source/drain and having a right surface that contacts a second insulator line that is parallel to the first insulator line.

10. The memory device of claim 9, wherein a shape of a top surface of the conductive contact region is approximately a rectangle.

11. The memory device of claim 9, wherein the pillar is approximately a rectangular prism and the bottom electrode is approximately a cylinder.

12. The memory device of claim 9, wherein a distance between memory cells along a direction parallel to the first insulator line and the second insulator line is smaller than a distance between memory cells along a direction perpendicular to the first insulator line and the second insulator line.

13. The memory device of claim 9, wherein a first plurality of bottom electrodes, included in a first plurality of capacitors that extends along a direction perpendicular to the first insulator line and the second insulator line, are in contact with a corresponding plurality of first conductive regions.

14. The memory device of claim 13, wherein a second plurality of bottom electrodes, included in a second plurality of capacitors that is adjacent to the first plurality of capacitors, are in contact with a corresponding plurality of second conductive regions.

15. The memory device of claim 9, wherein consecutive bottom electrodes, included in a plurality of capacitors that extends along a direction parallel to the first insulator line and the second insulator line, alternate between being in contact with a respective first conductive region and a respective second conductive region.

16. The memory device of claim 9, wherein consecutive conductive contact regions, included in a column of memory cells that extends along a direction parallel to the first insulator line and the second insulator line, are separated by respective insulative spacer regions that each abut the first insulator line and the second insulator line.

17. A method, comprising:
forming a pillar that includes an upper source/drain, a lower source/drain, and a channel between the upper source/drain and the lower source/drain;
forming a first gate line, wherein a portion of the first gate line is proximate to the channel on a first side of the pillar and is separated from the channel by an insulative material;
forming a second gate line parallel to the first gate line, wherein a portion of the second gate line is proximate to the channel on a second side of the pillar, that is opposite the first side, and is separated from the channel by the insulative material;
forming a first insulator line, wherein a portion of the first insulator line is proximate to the upper source/drain on the first side of the pillar;
forming a second insulator line parallel to the first insulator line, wherein a portion of the second insulator line is proximate to the upper source/drain on the second side of the pillar; and
forming a conductive contact region that includes the upper source/drain, a first conductive region in contact with the upper source/drain and the first insulator line, and a second conductive region in contact with the upper source/drain and the second insulator line.

18. The method of claim 17, further comprising forming an insulative spacer region that comprises the insulative material, wherein the insulative spacer region abuts the first insulator line and the second insulator line and separates the conductive contact region from an adjacent conductive contact region associated with an adjacent pillar.

19. The method of claim 17, wherein the conductive contact region is centered over the channel or the upper source/drain.

20. The method of claim 17, further comprising forming a capacitor that includes a top electrode, an insulator, and a cylindrical bottom electrode, wherein the cylindrical bottom electrode is in contact with the conductive contact region.
